(19) United States
(12) Patent Application Publication
(10) Pub. No.: US 2026/0271534 A1
(43) Pub. Date: Sep. 10, 2026

(54) DISPLAY DEVICE AND ELECTRONIC DEVICE INCLUDING THE SAME

(71) Applicant: Samsung Display Co., Ltd., Yongin-si (KR)

(72) Inventors: Sang Hoon LEE, Yongin-si (KR); Seung Ki SONG, Yongin-si (KR); Han Ggoch Nu Ri JO, Yongin-si (KR)

(21) Appl. No.: 19/384,672

(22) Filed: Nov. 10, 2025

(30) Foreign Application Priority Data
Mar. 5, 2025 (KR) 10-2025-0028401

(51) Int. Cl. H10K 59/122

(52) U.S. Cl. CPC H10K 59/122

(57) ABSTRACT

A display device includes: anode electrodes on a substrate, and overlapping with emission areas, respectively; and a pixel defining layer having an opening overlapping with each of the anode electrodes, the pixel defining layer including: a first portion between emission areas adjacent to each other in a plan view and to emit light of a same color as each other; and a second portion between emission areas to emit light of different colors from each other. Each of the first portion and the second portion includes a protrusion protruding from an edge of the opening in a direction toward a center of the opening to have an undercut structure at the edge of the opening, and a protruding width of a portion of the protrusion corresponding to the first portion and a protruding width of a portion of the protrusion corresponding to the second portion are different from each other.

### CROSS-REFERENCE TO RELATED APPLICATION

The present application claims priority to and the benefit of Korean Patent Application No. 10-2025-0028401, filed on March 05, 2025, in the Korean Intellectual Property Office, the entire disclosure of which is incorporated by reference herein.

### BACKGROUND

### 1. Field

Aspects of embodiments of present disclosure relate to a display device, and an electronic device including the display device.

### 2. Description of the Related Art

With the recent interest in information displays, research and development of display devices are ongoing.

### SUMMARY

One or more embodiments of the present disclosure may be directed to a display device having improved reliability.

One or more embodiments of the present disclosure may be directed to an electronic device including the display device.

However, the present disclosure is not limited to the above aspects and features. The above and additional aspects and features will be set forth, in part, in the description that follows, and in part, may be apparent from the description, or may be learned by practicing one or more of the presented embodiments of the present disclosure.

According to one or more embodiments of the present disclosure, a display device includes: a substrate; anode electrodes on the substrate, and overlapping with emission areas, respectively; and a pixel defining layer covering an edge of each of the anode electrodes, defining each of the emission areas, and having an opening overlapping with each of the anode electrodes, the pixel defining layer including: a first portion between emission areas adjacent to each other in a plan view and configured to emit light of a same color as each other from among the emission areas; and a second portion between emission areas configured to emit light of different colors from each other from among the emission areas. Each of the first portion and the second portion includes a protrusion protruding from an edge of the opening in a direction toward a center of the opening to have an undercut structure at the edge of the opening, and a protruding width of a portion of the protrusion corresponding to the first portion and a protruding width of a portion of the protrusion corresponding to the second portion are different from each other.

In an embodiment, the protruding width of the portion of the protrusion corresponding to the first portion may be smaller than the protruding width of the portion corresponding to the second portion.

In an embodiment, the protruding width of the portion of the protrusion corresponding to the first portion may be in a range of greater than 0 nm and less than 110 nm, and the protruding width of the portion of the protrusion corresponding to the second portion may be in a range of greater than or equal to 35 nm and less than or equal to 250 nm.

In an embodiment, the pixel defining layer may include: a first pixel defining layer on the anode electrodes; and a second pixel defining layer on the first pixel defining layer, and having a width greater than a width of the first pixel defining layer.

In an embodiment, the second pixel defining layer may include the protrusion protruding from the first pixel defining layer in the direction toward the center of the opening in a plan view.

In an embodiment, a protrusion length, from the first pixel defining layer in a plan view, of a portion of the second pixel defining layer corresponding to the first portion may be less than a protrusion length, from the first pixel defining layer in a plan view, of a portion of the second pixel defining layer corresponding to the second portion.

In an embodiment, a thickness of a portion of the second pixel defining layer corresponding to the first portion may be less than a thickness of a portion of the second pixel defining layer corresponding to the second portion.

In an embodiment, the pixel defining layer may further include a third pixel defining layer between the first pixel defining layer and the anode electrodes.

In an embodiment, the third pixel defining layer may have a width greater than the width of the first pixel defining layer.

In an embodiment, a slope of a side surface of a portion of the third pixel defining layer corresponding to the first portion may be smaller than a slope of a side surface of a portion of the third pixel defining layer corresponding to the second portion.

In an embodiment, the display device may further include: a light-emitting structure on the pixel defining layer, and including light-emitting units, and a charge generation layer between the light-emitting units; and a cathode electrode on the light-emitting structure, and connected entirely through an area overlapping with the first portion of the pixel defining layer. The charge generation layer may be discontinuous in an area overlapping with the second portion of the pixel defining layer.

According to one or more embodiments of the present disclosure, a display device includes: a substrate; anode electrodes on the substrate, and overlapping with emission areas, respectively; and a pixel defining layer covering an edge of each of the anode electrodes, defining each of the emission areas, and having an opening overlapping with each of the anode electrodes, the pixel defining layer including: a first portion between emission areas adjacent to each other in a plan view and configured to emit light of a same color as each other from among the emission areas; and a second portion between emission areas configured to emit light of different colors from each other from among the emission areas. A thickness of the first portion and a thickness of the second portion are different from each other.

In an embodiment, the thickness of the first portion may be less than the thickness of the second portion.

In an embodiment, the thickness of the first portion may be in a range of greater than 0 nm and less than 400 nm, and the thickness of the second portion may be in a range of greater than or equal to 250nm and less than or equal to 420nm.

In an embodiment, the pixel defining layer may include: a first pixel defining layer on the anode electrodes; and a second pixel defining layer on the first pixel defining layer, and having a width greater than a width of the first pixel defining layer.

In an embodiment, a thickness of a portion of the second pixel defining layer corresponding to the first portion may be less than a thickness of a portion of the second pixel defining layer corresponding to the second portion.

In an embodiment, the pixel defining layer may further include a third pixel defining layer between the first pixel defining layer and the anode electrodes.

In an embodiment, the third pixel defining layer may have a width greater than the width of the first pixel defining layer.

In an embodiment, a slope of a side surface of a portion of the third pixel defining layer corresponding to the first portion may be less than a slope of a side surface of a portion of the third pixel defining layer corresponding to the second portion.

According to one or more embodiments of the present disclosure, an electronic device includes: a processor; and a display device configured to display an image under control of the processor, the display device including: a substrate; anode electrodes on the substrate, and overlapping with emission areas, respectively; and a pixel defining layer covering an edge of each of the anode electrodes, defining each of the emission areas, and having an opening overlapping with each of the anode electrodes, the pixel defining layer including: a first portion between emission areas adjacent to each other in a plan view and configured to emit light of a same color as each other from among the emission areas; and a second portion between emission areas configured to emit light of different colors from each other from among the emission areas. Each of the first portion and the second portion includes a protrusion protruding from an edge of the opening in a direction toward a center of the opening to have an undercut structure at the edge of the opening, and a protruding width of a portion of the protrusion corresponding to the first portion and a protruding width of a portion of the protrusion corresponding to the second portion are different from each other. A number of pixels per inch (ppi) of the display device is greater than or equal to 1000 ppi.

According to some embodiments of the present disclosure, by configuring a structure of a pixel defining layer disposed between emission areas for emitting light of the same color as each other differently from a structure of a pixel defining layer disposed between emission areas for emitting light of different colors from each other, cathode electrodes may not be disconnected between the emission areas for emitting light of the same color as each other. Further, a charge generation layer may be disconnected between the emission areas for emitting light of different colors from each other. Accordingly, the cathode electrode may be connected as a whole without floating parts on the display area through an area overlapping with a first portion, and the charge generation layer may be disconnected in an area overlapping with a second portion to reduce a current flowing to neighboring sub-pixels so as to prevent or substantially prevent or substantially prevent or substantially prevent color mixing. Thus, a reliability of the display device may be improved.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram illustrating an embodiment of a display device.

FIG. 2 is a block diagram illustrating an embodiment of any one sub-pixel of FIG. 1.

FIG. 3 is a circuit diagram illustrating an embodiment of the sub-pixel of FIG. 2.

FIG. 4 is a plan view illustrating an embodiment of a display panel of FIG. 1.

FIG. 5 is an exploded perspective view illustrating a portion of the display panel of FIG. 4.

FIG. 6 is a plan view illustrating an embodiment of pixels of FIG. 5.

FIG. 7 is a cross-sectional view taken along the line I-I' of FIG. 6 according to an embodiment.

FIG. 8 is an enlarged view illustrating the area A of FIG. 7.

FIG. 9 is a cross-sectional view illustrating an embodiment of a portion of a light-emitting structure included in any one of first to third light-emitting elements of FIG. 7.

FIG. 10 is a cross-sectional view illustrating an embodiment of a portion of a light-emitting structure included in any one of first to third light-emitting elements of FIG. 7.

FIG. 11 is a cross-sectional view taken along the line II-II' of FIG. 6.

FIG. 12 is a cross-sectional view taken along the line III-III' of FIG. 6.

FIG. 13 is a cross-sectional view taken along the line II-II' of FIG. 6.

FIG. 14 is a cross-sectional view taken along the line II-II' of FIG. 6.

FIG. 15 is a cross-sectional view taken along the line II-II' of FIG. 6.

FIG. 16 is a cross-sectional view taken along the line III-III' of FIG. 6.

FIG. 17 is a cross-sectional view taken along the line II-II' of FIG. 6.

FIG. 18 is a cross-sectional view taken along the line III-III' of FIG. 6.

FIG. 19 is a plan view illustrating an arrangement of the pixels of FIG. 6 according to an embodiment.

FIG. 20 is a plan view illustrating an arrangement of the pixels of FIG. 6 according to an embodiment.

FIGS. 21-37 illustrate a method of manufacturing a display device according to an embodiment.

FIG. 38 is a block diagram of an electronic device according to an embodiment.

FIG. 39 is a schematic diagram of an electronic device according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the first direction DR1, the second direction DR2, and the third direction DR3are not limited to three axes (for example, x-axis, y-axis and z-axis) of the rectangular coordinate system, and may be interpreted in a broader sense. For example, the first direction DR1, the second direction DR2, and the third direction DR3 may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

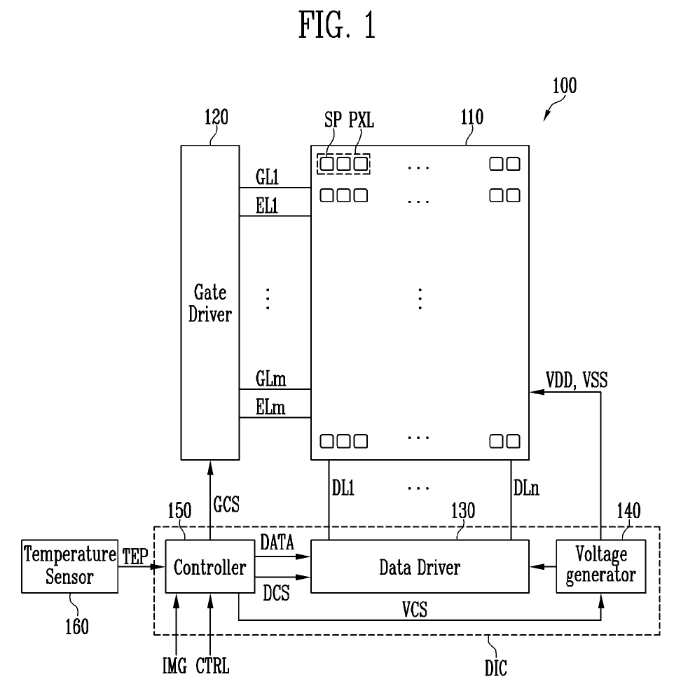

FIG. 1 is a block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm, where m is an integer greater than 1. The sub-pixels SP may be connected to the data driver 130 through first to n-th data lines DL1 to DLn, where n is an integer greater than 1.

Each of the sub-pixels SP may include at least one light emitting element to generate light. Accordingly, each of the sub-pixels SP may generate light in a desired color (e.g., a specific or predetermined color), such as red, green, blue, cyan, magenta, or yellow. Two or more sub-pixels among the sub-pixels SP may form one pixel PXL. For example, as illustrated in FIG. 1, three sub-pixels SP may form one pixel PXL.

The gate driver 120 may be connected to the sub-pixels SP arranged along a row direction through the first to m-th gate lines GL1 to GLm. The gate driver 120 may output gate signals to the first to m-th gate lines GL1 to GLm in response to a gate control signal GCS. In some embodiments, the gate control signal GCS may include a start signal for instructing each frame to start, a horizontal synchronization signal for outputting gate signals in synchronization with a timing at which data signals are applied, and the like.

In some embodiments, first to m-th emission control lines EL1 to ELm that are connected to the sub-pixels SP along the row direction may be further provided. In this case, the gate driver 120 may include an emission control driver to control the first to m-th emission control lines EL1 to ELm. The emission control driver may operate under the control of the controller 150.

The gate driver 120 may be disposed on one side of the display panel 110. However, the present disclosure is not limited thereto. For example, the gate driver 120 may be divided into two or more drivers that are physically and/or logically distinguished from each other. The drivers may be disposed on a first side of the display panel 110, and a second side of the display panel 110 opposite to the first side. As such, the gate driver 120 may be disposed around the display panel 110 in various suitable configurations as needed or desired.

The data driver 130 may be connected to the sub-pixels SP arranged along a column direction through the first to n-th data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and the like.

The data driver 130 may apply, using voltages from the voltage generator 140, data signals having grayscale voltages (e.g., grayscale voltage values or levels) corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Thus, associated sub-pixels SP may generate light corresponding to the data signals. As a result, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 may generate a plurality of voltages, and may provide the generated voltages to the components of the display device 100. For example, the voltage generator 140 may receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively higher voltage level. The second power voltage VSS may have a voltage level lower than that of the first power voltage VDD. In other embodiments, the first power voltage VDD or the second power voltage VSS may be provided by an external device of the display device 100.

In addition, the voltage generator 140 may generate various suitable voltages. For example, the voltage generator 140 may generate an initialization voltage to be applied to the sub-pixels SP. For example, during a sensing operation for sensing electrical characteristics of transistors and/or light emitting elements of the sub-pixels SP, a reference voltage (e.g., a certain or predetermined reference voltage) may be applied to each of the first to n-th data lines DL1 to DLn. The voltage generator 140 may generate the reference voltage.

The controller 150 may control the overall operations of the display device 100. The controller 150 may receive input image data IMG and a control signal CTRL from an external device to control an operation of displaying the input image data IMG. The controller 150 may provide a gate control signal GCS, a data control signal DCS, and a voltage control signal VCS, in response to the control signal CTRL.

The controller 150 may convert the input image data IMG to be suitable for the display device 100 or the display panel 110, and then may output image data DATA. In some embodiments, the controller 150 may align the input image data IMG to be suitable for the sub-pixels SP on a row basis, and may then output the image data DATA.

Two or more components of the data driver 130, the voltage generator 140, and/or the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, and/or the controller 150 may be provided as a component separate from the driver integrated circuit DIC.

The display device 100 may include at least one temperature sensor 160. The temperature sensor 160 may sense a peripheral temperature, and may generate temperature data TEP indicating the sensed temperature. In some embodiments, the temperature sensor 160 may be disposed adjacent to the display panel 110 and/or the driver integrated circuit DIC.

The controller 150 may control various operations of the display device 100 in response to the temperature data TEP. In some embodiments, the controller 150 may adjust the luminance of an image output from the display panel 110 in response to the temperature data TEP. For example, the controller 150 may control components such as the data driver 130 and/or the voltage generator 140, and thus, adjusting data signals and the first and second power voltages VDD and VSS.

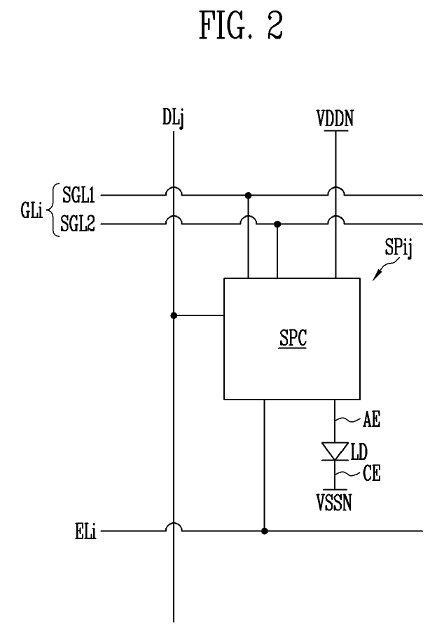

FIG. 2 is a block diagram illustrating an embodiment of any one sub-pixel of FIG. 1. In FIG. 2, a sub-pixel SPij disposed on an i-th row (where i is an integer equal to or greater than 1 and less than or equal to m) and a j-th column (where j is an integer equal to or greater than 1 and less than or equal to n) from among the sub-pixels SP of FIG. 1 is illustrated.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN may be a node that transmits the first power voltage VDD of FIG. 1. The second power voltage node VSSN may be a node that transmits the second power voltage VSS of FIG. 1.

An anode electrode AE of the light emitting element LD may be connected to the first power voltage node VDDN through the sub-pixel circuit SPC. A cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may control the light emitting element LD in response to signals received through the aforementioned signal lines.

The sub-pixel circuit SPC may operate in response to a gate signal received through the i-th gate line GLi. The i-th gate line GLi may include one or more sub-gate lines. In some embodiments, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in a case where the i-th gate line GLi includes two or more sub-gate lines, the sub-pixel circuit SPC may operate in response to gate signals received through the corresponding two or more sub-gate lines.

The sub-pixel circuit SPC may operate in response to an emission control signal received through the i-th emission control line ELi. In some embodiments, the i-th emission control line ELi may include one or more sub-emission control lines. In a case where the i-th emission control line ELi includes two or more sub-emission control lines, the sub-pixel circuit SPC may operate in response to emission control signals received through the corresponding two or more sub-emission control lines.

The sub-pixel circuit SPC may receive a data signal through a j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light emitting element LD according to the stored voltage, in response to an emission control signal received through the i-th emission control line ELi. Therefore, the light emitting element LD may generate light having a luminance corresponding to the data signal.

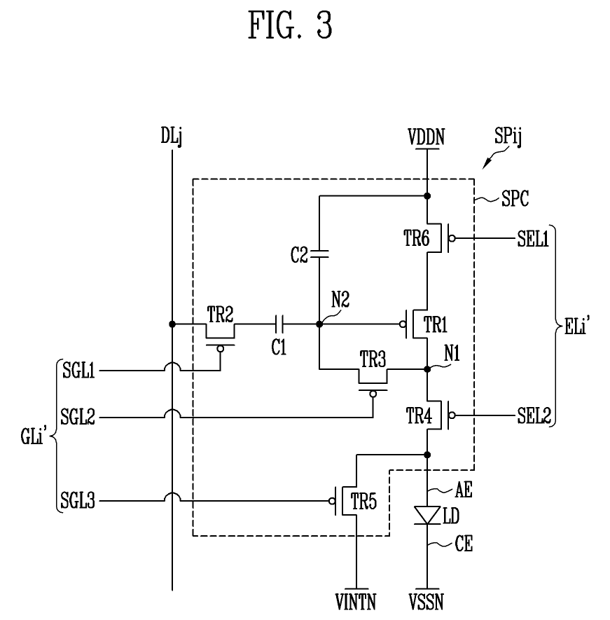

FIG. 3 is a circuit diagram illustrating an embodiment of the sub-pixel of FIG. 2.

Referring to FIG. 3, the sub-pixel SPij may include a sub-pixel circuit SPC and a light emitting element LD.

The sub-pixel circuit SPC may be connected to an i-th gate line GLi’, an i-th emission control line ELi’, and a j-th data line DLj. Compared to the i-th gate line GLi described above with reference to FIG. 2, the i-th gate line GLi’ illustrated in FIG. 3 may further include a third sub-gate line SGL3. Compared to the i-th emission control line ELi described above with reference to FIG. 2, the i-emission control line ELi’ illustrated in FIG. 3 may include a first sub-emission control line SEL1 and a second sub-emission control line SEL2.

The sub-pixel circuit SPC may include first to sixth transistors TR1 to TR6, and first and second capacitors C1 and C2.

The first transistor TR1 is connected between the first power node VDDN and a first node N1. A gate of the first transistor TR1 may be connected to a second node N2. Thus, the first transistor TR1 may be turned on depending on the voltage level of the second node N2. The first transistor TR1 may be referred to as a driving transistor.

The second transistor TR2 may be connected between the j-th data line DLj and the second node N2. A gate of the second transistor TR2 may be connected to a first sub-gate line SGL1. Thus, the second transistor TR2 may be turned on in response to a gate signal of the first sub-gate line SGL1. The second transistor TR2 may be referred to as a switching transistor.

The third transistors TR3 may be connected between the first node N1 and the second node N2. A gate of the third transistor TR3 may be connected to a second sub-gate line SGL2. Thus, the third transistor TR3 may be turned on in response to a gate signal of the second sub-gate line SGL2.

The fourth transistor TR4 may be connected between the first node N1 and the anode electrode AE of the light emitting element LD. A gate of the fourth transistor TR4 may be connected to the second sub-emission control line SEL2. Thus, the fourth transistor TR4 may be turned on in response to an emission control signal of the second sub-emission control line SEL2.

The fifth transistor TR5 may be connected between the anode electrode AE of the light emitting element LD and an initialization voltage node VINTN. The initialization voltage node VINTN may transmit an initialization voltage. In some embodiments, the initialization voltage may be provided by the voltage generator 140 of FIG. 1. In other embodiments, the initialization voltage may be provided by an external device of the display device 100. A gate of the fifth transistor TR5 may be connected to the third sub-gate line SGL3. Thus, the fifth transistor TR5 may be turned on in response to a gate signal of the third sub-gate line SGL3.

The sixth transistor TR6 is connected between the first power voltage node VDDN and the first transistor TR1. A gate of the sixth transistor TR6 may be connected to the first sub-emission control line SEL1. Thus, the sixth transistor TR6 may be turned on in response to an emission control signal of the first sub-emission control line SEL1.

The first capacitor C1 is connected between the second transistor TR2 and the second node N2. The second capacitor C2 is connected between the first power voltage node VDDN and the second node N2.

As such, the sub-pixel circuit SPC may include the first to sixth transistors TR1 to TR6 and the first and second capacitors C1 and C2. However, the present disclosure is not limited thereto. The sub-pixel circuit SPC may be implemented as any one of various suitable forms of circuits, each including a plurality of transistors and one or more capacitors. For example, the sub-pixel circuit SPC may include two transistors and one capacitor. The number of sub-gate lines included in the i-th gate line GLi’ and the number of sub-emission control lines included in the i-th emission control line ELi’ may also be variously modified depending on a configuration of the sub-pixel circuit SPC.

The first to sixth transistors TR1 to TR6 may be formed of P-type transistors. Each of the first to sixth transistors TR1 to TR6 may be formed of a metal oxide semiconductor field effect transistor (MOSFET). However, the present disclosure is not limited thereto. For example, at least one of the first to sixth transistors TR1 to TR6 may be replaced with to an N-type transistor.

In some embodiments, the first to sixth transistors TR1 to TR6 may include an amorphous silicon semiconductor, a monocrystalline silicon semiconductor, a polycrystalline silicon semiconductor, an oxide semiconductor, or the like.

The light emitting element LD may include the anode electrode AE, the cathode electrode CE, and a light-emitting layer. The light-emitting layer may be disposed between the anode electrode AE and the cathode electrode CE. When emission control signals of the first and second sub-emission control lines SEL1 and SEL2 are enabled to an on level (e.g., a low level) after a data signal transmitted through the j-th data line DLj is reflected in the voltage of the second node N2, the fourth and sixth transistors TR4 and TR6 may be turned on. Furthermore, the first transistor TR1 may be turned on in response to the voltage of the second node N2, so that a current may flow from the first power voltage node VDDN to the second power voltage node VSSN. The light emitting element LD may emit light corresponding to an amount of the current.

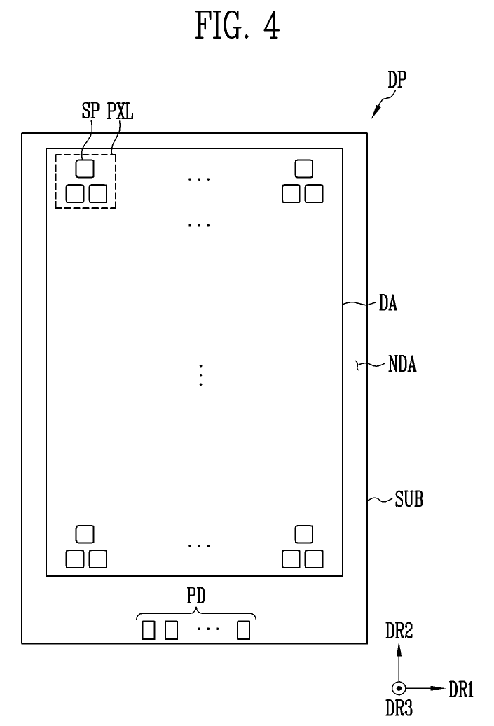

FIG. 4 is a plan view illustrating an embodiment of the display panel of FIG. 1.

Referring to FIG. 4, the display DP, which may be an embodiment of the display panel 110 described above with reference to FIG. 1, may include a display area DA and a non-display area NDA. The display panel DP may display an image through the display area DA. The non-display area NDA may be around the display area DA.

The display panel DP may include a substrate SUB, sub-pixels SP, and pads PD.

In a case where the display panel DP is used as a display screen for a head-mounted display (HMD), a virtual reality (VR) device, a mixed reality (MR) device, an augmented reality (AR) device, and/or the like, the display panel DP may be positioned to be close (e.g., extremely close) to the eyes of the user. In this case, relatively high-density sub-pixels SP may be desired. To increase the pixel density of the sub-pixels SP, the substrate SUB may be provided using a silicon substrate. The sub-pixels SP and/or the display panel DP may be formed on the substrate SUB that is a silicon substrate. The display device 100 (e.g., refer to FIG. 1) including the display panel DP formed on the substrate SUB that is a silicon substrate may be referred to as an OLED on Silicon (OLEDoS) display device.

The sub-pixels SP may be disposed in the display area DA on the substrate SUB. The sub-pixels SP may be arranged in the form of a matrix along a first direction DR1 and a second direction DR2 crossing or intersecting with the first direction DR1. However, the present disclosure is not limited thereto. For example, the sub-pixels SP may be arranged in a zigzag pattern along the first direction DR1 and the second direction DR2. For example, the sub-pixels SP may be arranged in an RGBG from (e.g., a PENTILE^{®} form, PENTILE^{®} being a duly registered trademark of Samsung Display Co., Ltd.). The first direction DR1 may refer to a row direction, and the second direction DR2 may refer to a column direction.

Two or more sub-pixels among the sub-pixels SP may form one pixel PXL.

Components for controlling the sub-pixels SP may be disposed in the non-display area NDA on the substrate SUB. For example, lines, such as the first to m-th gate lines GL1 to GLm and the first to n-th data lines DL1 to DLn described above with reference to FIG. 1, that are connected to the sub-pixels SP may be disposed in the non-display area NDA.

At least one of the gate driver 120, the data driver 130, the voltage generator 140, the controller 150, and/or the temperature sensor 160 of FIG. 1 may be integrated in the non-display area NDA of the display panel DP. In some embodiments, the gate driver 120 of FIG. 1 may be mounted on the display panel DP and positioned in the non-display area NDA. In other embodiments, the gate driver 120 may be implemented as an integrated circuit separate from the display panel DP. In some embodiments, the temperature sensor 160 may be positioned in the non-display area NDA to sense the temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device 100 (e.g., refer to FIG. 1). In some embodiments, voltages and signals used for the operations of the components included in the display panel DP may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in a case where the gate driver 120 is mounted on the display panel DP, the gate control signal GCS may be transmitted from the driver integrated circuit DIC to the gate driver 120 through the pads PD.

In some embodiments, a circuit board may be electrically connected to the pads PD by a conductive adhesive component, such as an anisotropic conductive film. The circuit board may be a flexible printed circuit board (FPCB) or flexible film that is made of a flexible material. The driver integrated circuit DIC may be mounted on the circuit board, and may be electrically connected to the pads PD.

In some embodiments, the display area DA may have various suitable shapes. The display area DA may have a closed-loop shape, including linear and/or curved sides. For example, the display area DA may have a suitable shape, such as a polygon, a circle, a semicircle, and/or an ellipse.

In some embodiments, the display panel DP may have a planar display surface. In other embodiments, the display panel DP may have a display surface that is at least partially rounded or curved. In some embodiments, the display panel DP may be bendable, foldable, or rollable. In these cases, the display panel DP and/or the substrate SUB may include various suitable materials having flexible properties.

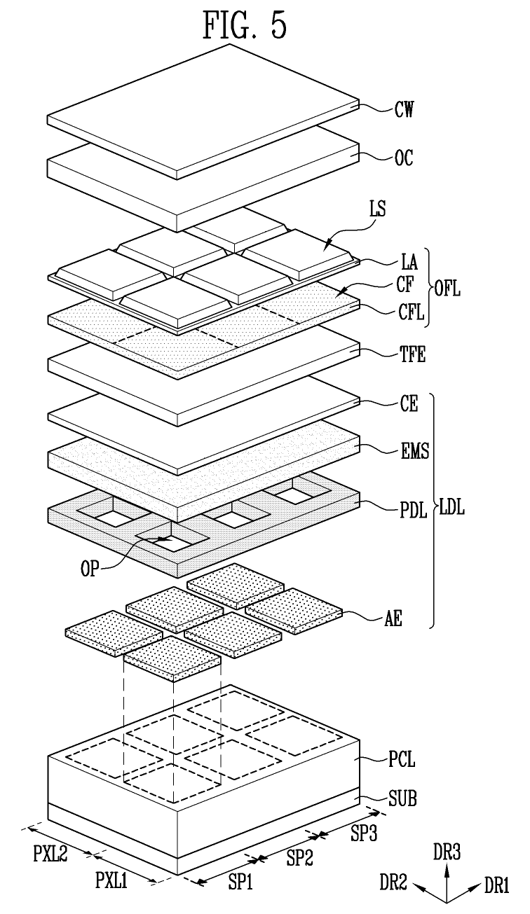

FIG. 5 is an exploded perspective view illustrating a portion of the display panel of FIG. 4. In FIG. 5, for convenience of illustration, a portion of the display panel DP corresponding to two pixels PXL1 and PXL2 among the pixels PXL of FIG. 4 is schematically illustrated. The remaining portions of the display panel DP corresponding to the other pixels may also be configured in the same or substantially the same manner.

Referring to FIGS. 4 and 5, each of first and second pixels PXL1 and PXL2 may include first to third sub-pixels SP1, SP2, and SP3. However, the present disclosure is not limited thereto. For example, each of the first and second pixels PXL1 and PXL2 may include four sub-pixels, or may include two sub-pixels.

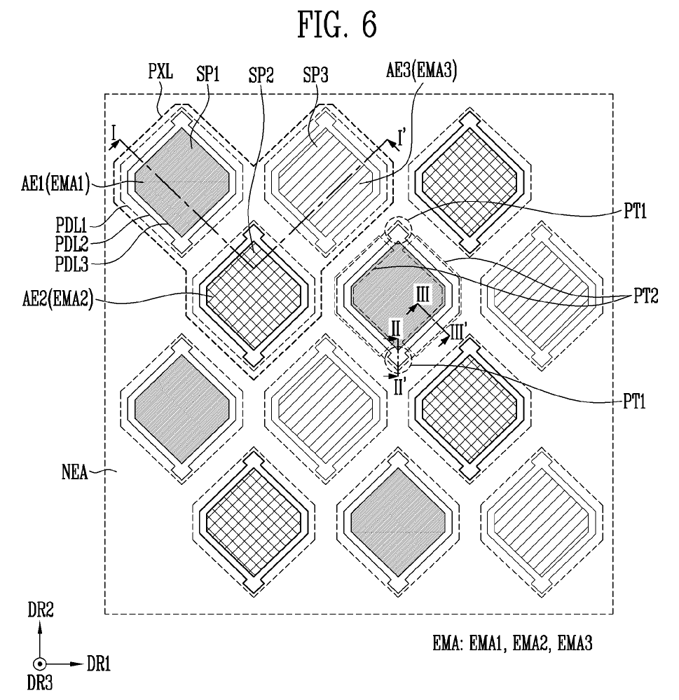

In FIG. 5 a case where the first to third sub-pixels SP1, SP2, and SP3 have rectangular shapes and the same or substantially the same size as each other when viewed in a third direction DR3 crossing or intersecting with the first and second directions DR1 and DR2 (e.g., in a plan view) is illustrated. However, the present disclosure is not limited thereto. The first to third sub-pixels SP1 to SP3 may be variously modified to have various suitable arrangements and shapes (e.g., see FIG. 6) as needed or desired.

The display panel DP may include a substrate SUB, a pixel circuit layer PCL, a light-emitting element layer LDL, an encapsulation layer TFE, an optical functional layer OFL, an overcoat layer OC, and a cover window CW.

In some embodiments, the substrate SUB may include a silicon wafer substrate formed through a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In some embodiments, the substrate SUB may include a glass substrate. In some embodiments, the substrate SUB may include a polyimide (PI) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least portions of the circuit components, lines, or the like. The conductive patterns may include copper, but the present disclosure is not limited thereto.

The circuit elements may respectively include sub-pixel circuits SPC (e.g., refer to FIG. 2) of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping with the semiconductor portion. In some embodiments, in a case where the substrate SUB is formed of a silicon substrate, the semiconductor portion may be included in the substrate SUB, and the gate electrode may be included in the pixel circuit layer PCL as a conductive pattern of the pixel circuit layer PCL. In an embodiment, in a case where the substrate SUB is formed of a glass substrate or a PI substrate, the semiconductor portion and the gate electrode may be included in the pixel circuit layer PCL. Each capacitor may include electrodes that are spaced apart from each other. For example, each capacitor may include electrodes that are spaced apart from each other on a plane defined in the first and second directions DR1 and DR2. For example, each capacitor may include electrodes that are spaced apart from each other in the third direction DR3 with an insulating layer interposed therebetween.

The lines of the pixel circuit layer PCL may include signal lines connected to each of the first to third sub-pixels SP1, SP2, and SP3, for example, such as a gate line, an emission control line, and a data line. The lines may further include a line connected to the first power voltage node VDDN of FIG. 2. Furthermore, the lines may further include a line connected to the second power voltage node VSSN of FIG. 2.

The light-emitting element layer LDL may include anode electrodes AE, a pixel defining layer PDL, a light-emitting structure EMS, and a cathode electrode CE.

The anode electrodes AE may be disposed on the pixel circuit layer PCL. The anode electrodes AE may contact circuit elements of the pixel circuit layer PCL. The anode electrodes AE may include an opaque conductive material capable of reflecting light, but the present disclosure is not limited thereto.

The pixel defining layer PDL may be disposed on the anode electrodes AE. The pixel defining layer PDL may include openings OP that overlap with respective portions of the anode electrodes AE. Respective emission areas corresponding to the first to third sub-pixels SP1 to SP3 may be defined according to the openings OP in the pixel defining layer PDL. As another example, the respective emission areas corresponding to the first to third sub-pixels SP1 to SP3 may be understood as being defined according to the anode electrodes AE. In an area adjacent to a boundary of neighboring sub-pixels, the pixel defining layer PDL may include a separator that causes a discontinuity to be formed in the light-emitting structure EMS. In this case, the respective emission areas corresponding to the first to third sub-pixels SP1 to SP3 may be understood as being defined by the separators of the pixel defining layer PDL.

In some embodiments, the pixel defining layer PDL may include an inorganic material. In this case, the pixel defining layer PDL may include a plurality of inorganic layers stacked on top of one another. For example, the pixel defining layer PDL may include silicon oxide (SiOₓ) and silicon nitride (SiNx). Because the pixel defining layer PDL includes the inorganic materials, it may be easy to manufacture the pixel defining layer PDL in micro-units during a manufacturing process. Accordingly, a high-resolution display device having a number of pixels per inch (ppi) of about 1000 ppi or more per unit area of the display device 100 (e.g., see FIG. 1) may be implemented. In an embodiment, the pixel defining layer PDL may include an organic material. However, the material of the pixel defining layer PDL is not limited to the aforementioned examples.

The light-emitting structure EMS may be disposed on the anode electrodes AE exposed through the openings OP in the pixel defining layer PDL. The light-emitting structure EMS may include a light-emitting layer to generate light, an electron transport layer to transport electrons, and a hole transport layer to transport holes.

In some embodiments, the light-emitting structure EMS may fill the openings OP in the pixel defining layer PDL, and may be disposed on an overall surface of an upper portion of the pixel defining layer PDL. In other words, the light-emitting structure EMS may extend over the first to third sub-pixels SP1 to SP3. In this case, at least some of the layers in the light-emitting structure EMS may be interrupted or bent at boundaries between the first to third sub-pixels SP1 to SP3. However, the present disclosure is not limited thereto. For example, portions of the light-emitting structure EMS corresponding to the first to third sub-pixels SP1 to SP3 may be spaced apart (e.g., separated) from each other, and each of the portions may be disposed in a corresponding opening OP in the pixel defining layer PDL.

The cathode electrode CE may be disposed on the light-emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin-film metal layer having a suitable thickness allowing light emitted from the light-emitting structure EMS to pass therethrough. The cathode electrode CE may be made of a metal material having a relatively small thickness, or a transparent conductive material. In some embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, or gallium tin oxide. In some embodiments, the cathode electrode CE may include at least one of silver (Ag), magnesium (Mg), and/or a suitable compound thereof. However, the material of the cathode electrode CE is not limited to the aforementioned examples.

Any one of the anode electrodes AE, a portion of the light-emitting structure EMS that overlaps with the any one anode electrode AE, and a portion of the cathode electrode CE that overlaps with the portion of the light-emitting structure EMS may be understood as constituting one light emitting element LD (e.g., refer to FIG. 2). In other words, each of the light emitting elements LD of the first to third sub-pixels SP1 to SP3 may include one anode electrode AE, a portion of the light-emitting structure EMS that overlaps with the one anode electrode AE, and a portion of the cathode electrode CE that overlaps with the portion of the light-emitting structure EMS. In each of the first to third sub-pixels SP1 to SP3, holes injected from the anode electrode AE and electrons injected from the cathode electrode CE are transported into the light-emitting layer of the light-emitting structure EMS, thus forming excitons. When the excitons make a transition from an excited state to a ground state, light may be generated. Depending on the amount of current flowing through the light-emitting layer, the luminance of light may be determined. Depending on the configuration of the light-emitting layer, the wavelength range of light to be generated may be determined.

The encapsulation layer TFE may be disposed on the cathode electrode CE. The encapsulation layer TFE may cover the light-emitting element layer LDL and/or the pixel circuit layer PCL. The encapsulation layer TFE may prevent or substantially prevent oxygen, water, and/or the like from penetrating into the light-emitting element layer LDL. In some embodiments, the encapsulation layer TFE may be formed by alternately stacking one or more inorganic layers and one or more organic layers. For example, the inorganic layer may include silicon nitride, silicon oxide, silicon oxynitride (SiOₓN_{y}), or the like. For example, the organic layer may include an organic insulating material, such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic layer and the inorganic layer of the encapsulation layer TFE are not limited to the aforementioned examples.

In order to improve the encapsulation efficiency of the encapsulation layer TFE, the encapsulation layer TFE may further include a thin film including aluminum oxide (AlOx). The thin film including aluminum oxide may be positioned on an upper surface of the encapsulation layer TFE facing the optical function layer OFL and/or on a lower surface of the encapsulation layer TFE facing the light emitting element layer LDL.

The thin film including aluminum oxide may be formed through an atomic layer deposition (ALD) method. However, the present disclosure is not limited thereto. The encapsulation layer TFE may further include a thin film formed of at least one of various suitable materials suitable for improving the encapsulation efficiency.

The optical functional layer OFL may be disposed on the encapsulation layer TFE. The optical functional layer OFL may include a color filter layer CFL and a lens layer LA.

The color filter layer CFL may be disposed between the encapsulation layer TFE and the lens layer LA. The color filter layer CFL may filter light emitted from the light-emitting structure EMS, and may selectively output light in a wavelength range or color corresponding to each sub-pixel. The color filter layer CFL may include color filters CF respectively corresponding to the first to third sub-pixels SP1 to SP3. Each of the color filters CF allows light within a desired wavelength range corresponding to the related sub-pixel to pass therethrough. For example, the color filter CF that corresponds to the first sub-pixel SP1 allows light in a red color to pass therethrough, the color filter CF that corresponds to the second sub-pixel SP2 allows light in a green color to pass therethrough, and the color filter CF that corresponds to the third sub-pixel SP3 allows light in a blue color to pass therethrough. Depending on the light emitted from the light-emitting structure EMS of each sub-pixel, at least some of the color filters CF may be omitted.

The lens layer LA may be disposed on the color filter layer CFL. The lens layer LA may include lenses LS that respectively correspond to the first to third sub-pixels SP1 to SP3. Each of the lenses LS may output and direct light emitted from the light-emitting structure EMS along an intended path, thus enhancing the light output efficiency. The lens layer LA may have a relatively high refractive index. For example, the lens layer LA may have a higher refractive index than that of the overcoat layer OC. In some embodiments, the lenses LS may include an organic material. In some embodiments, the lenses LS may include an acrylic material. However, the material of the lenses LS is not limited to the aforementioned example.

In some embodiments, compared to the opening OP of the pixel defining layer PDL, at least some of the color filters CF of the color filter layer CFL and at least some of the lenses LS of the lens layer LA may be shifted in a direction parallel to or substantially parallel to the plane defined in the first and second directions DR1 and DR2. In more detail, in a central area of the display area DA, the center of each color filter CF and the center of each lens LS may be aligned or overlap with the center of the corresponding opening OP of the pixel defining layer PDL. For example, in the central area of the display area DA, the opening OP of the pixel defining layer PDL may completely overlap with the corresponding color filter CF of the color filter layer CFL and the corresponding lens LS of the lens layer LA. In an area adjacent to the non-display area NDA within the display area DA, the center of the color filter CF and the center of the lens LS may be shifted in a planar direction from the center of the corresponding opening OP of the pixel defining layer PDL when viewed in the third direction DR3 (e.g., in a plan view). For example, in the area adjacent to the non-display area NDA within the display area DA, each opening OP of the pixel defining layer PDL may partially overlap with the corresponding color filter CF of the color filter layer CFL and the corresponding lens LS of the lens layer LA. Accordingly, light emitted from the light-emitting structure EMS in the central portion of the display area DA may be efficiently output in the normal direction of the display surface. Light emitted from the light-emitting structure EMS around the perimeter of the display area DA may be efficiently output in a direction inclined at a suitable angle (e.g., a certain or predetermined angle) with respect to the normal direction of the display surface.

The overcoat layer OC may be disposed on the lens layer LA. The overcoat layer OC may cover the optical functional layer OFL, the encapsulation layer TFE, the light-emitting structure EMS, and/or the pixel circuit layer PCL. The overcoat layer OC may include various suitable materials suitable for protecting the underlying layers from foreign substances, such as dust, water, or the like. For example, the overcoat layer OC may include at least one of an inorganic insulating layer and/or an organic insulating layer. For example, the overcoat layer OC may include an epoxy, but the present disclosure is not limited thereto. The overcoat layer OC may have a lower refractive index than that of the lens layer LA.

The cover window CW may be disposed on the overcoat layer OC. The cover window CW may protect the underlying layers. The cover window CW may have a higher refractive index than that of the overcoat layer OC. The cover window CW may include glass, but the present disclosure is not limited thereto. For example, the cover window CW may be an encapsulation glass layer to protect the components disposed thereunder. In other embodiments, the cover window CW may be omitted as needed or desired.

FIG. 6 is a plan view illustrating an embodiment of the pixels of FIG. 5. The pixel PXL of FIG. 6 may be one of the first pixel PXL1 or the second pixel PXL2 of FIG. 5.

Referring to FIG. 6, the pixel PXL (e.g., the first pixel PXL1 or the second pixel PXL2) may include first to third sub-pixels SP1 to SP3 arranged in a zigzag manner along the first direction DR1. The pixels PXL may be repeatedly arranged along the first direction DR1 and the second direction DR2.

The first sub-pixel SP1 may include a first emission area EMA1, and a non-emission area NEA formed around the first emission area EMA1. The second sub-pixel SP2 may include a second emission area EMA2, and the non-emission area NEA formed around the second emission area EMA2. The third sub-pixel SP3 may include a third emission area EMA3, and the non-emission area NEA formed around the third emission area EMA3.

The first emission area EMA1 may be an area where light is emitted from a portion of the light-emitting structure EMS (e.g., refer to FIG. 5) that corresponds to the first sub-pixel SP1. The second emission area EMA2 may be an area where light is emitted from a portion of the light-emitting structure EMS that corresponds to the second sub-pixel SP2. The third emission area EMA3 may be an area where light is emitted from a portion of the light-emitting structure EMS that corresponds to the third sub-pixel SP3.

The first emission area EMA1 is defined by the pixel defining layer PDL, and may correspond to an area where the first anode electrode AE1 corresponding to the first sub-pixel SP1 is exposed. In other words, the first emission area EMA1 may overlap with the first anode electrode AE1. The second emission area EMA2 is defined by the pixel defining layer PDL, and may correspond to an area where the second anode electrode AE2 corresponding to the second sub-pixel SP2 is exposed. In other words, the second emission area EMA2 may overlap with the second anode electrode AE2. The third emission area EMA3 is defined by the pixel defining layer PDL, and may correspond to an area where the third anode electrode AE3 corresponding to the third sub-pixel SP3 is exposed. In other words, the third emission area EMA3 may overlap with the third anode electrode AE3.

The pixel defining layer PDL covers edges of each of the first to third anode electrodes AE1 to AE3, and may expose a portion of each of the first to third anode electrodes AE1 to AE3.

The pixel defining layer PDL may include first to third pixel defining layers PDL1 to PDL3. The second pixel defining layer PDL2 may be disposed on the first pixel defining layer PDL1, and the third pixel defining layer PDL3 may be disposed under the first pixel defining layer PDL1.

The second pixel defining layer PDL2 may have a width greater than that of the first pixel defining layer PDL1. Therefore, the second pixel defining layer PDL2 may protrude further in a direction toward the first to third anode electrodes AE1 to AE3 than the first pixel defining layer PDL1. The third pixel defining layer PDL3 may also have a width greater than that of the first pixel defining layer PDL1. The third pixel defining layer PDL3 may have a width greater than that of the second pixel defining layer PDL2. Accordingly, the third pixel defining layer PDL3 may protrude further in the direction toward the first to third anode electrodes AE1 to AE3 than the first pixel defining layer PDL1 and the second pixel defining layer PDL2. However, the present disclosure is not limited thereto.

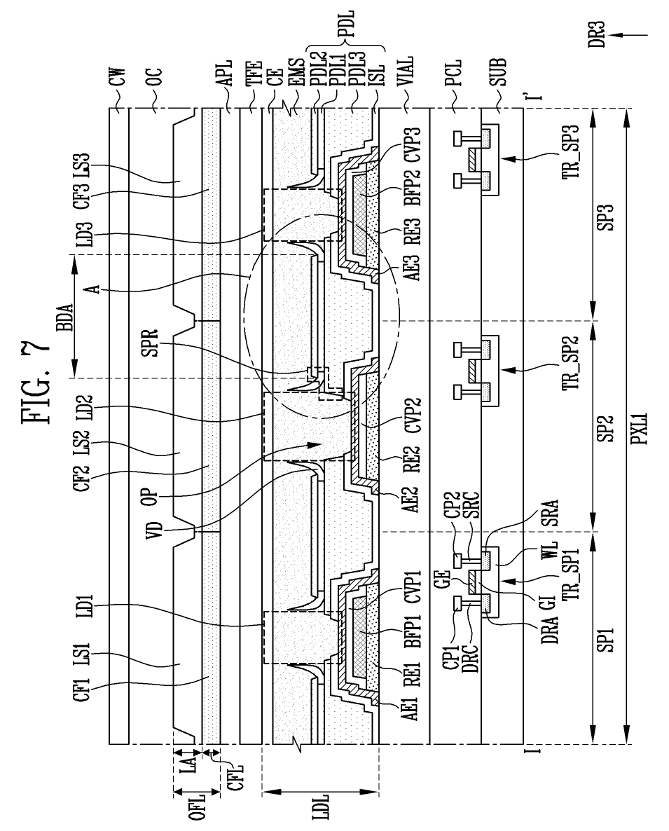

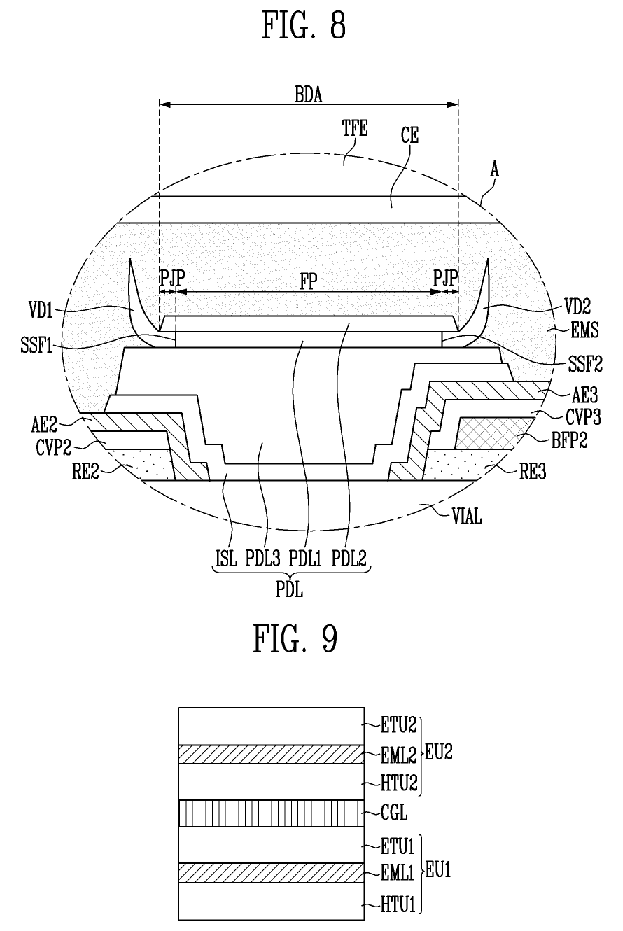

FIG. 7 is a cross-sectional view along the line I-I' of FIG. 6 according to an embodiment. FIG. 8 is an enlarged view illustrating the area A of FIG. 7.

Referring to FIG. 7, a substrate SUB and a pixel circuit layer PCL disposed on the substrate SUB may be provided.

The substrate SUB may include a silicon wafer substrate formed through a semiconductor process. For example, the substrate SUB may include silicon, germanium, and/or silicon-germanium.

The pixel circuit layer PCL may be disposed on the substrate SUB. The substrate SUB and the pixel circuit layer PCL may include respective circuit elements of the first to third sub-pixels SP1 to SP3. For example, the substrate SUB and the pixel circuit layer PCL may include a transistor TR_SP1 of the first sub-pixel SP1, a transistor TR_SP2 of the second sub-pixel SP2, and a transistor TR_SP3 of the third sub-pixel SP3. The transistor TR_SP1 of the first sub-pixel SP1 may be any one of the transistors included in the sub-pixel circuit SPC (e.g., refer to FIG. 2) of the first sub-pixel SP1. The transistor TR_SP2 of the second sub-pixel SP2 may be any one of the transistors included in the sub-pixel circuit SPC of the second sub-pixel SP2. The transistor TR_SP3 of the third sub-pixel SP3 may be any one of the transistors included in the sub-pixel circuit SPC of the third sub-pixel SP3. In FIG. 7, one of the transistors of each sub-pixel is illustrated for convenience of illustration, and the remaining circuit circuits are not shown.

The transistor TR_SP1 of the first sub-pixel SP1 may include a source area SRA, a drain area DRA, and a gate electrode GE.

The source area SRA and the drain area DRA may be disposed in the substrate SUB. Formed through an ion injection process, a well WL may be disposed in the substrate SUB. The source area SRA and the drain area DRA may be disposed to be spaced apart from each other in the well WL. An area between the source area SRA and the drain area DRA in the well WL may be defined as a channel area. The gate electrode GE may overlap with the channel area between the source area SRA and the drain area DRA, and may be disposed in the pixel circuit layer PCL. The gate electrode GE may be spaced apart from the well WL or the channel area by an insulating material, such as a gate insulating layer GI. The gate electrode GE may include a conductive material.

A plurality of layers included in the pixel circuit layer PCL may include insulating layers and conductive patterns disposed between the insulating layers. The conductive patterns may include first and second conductive patterns CP1 and CP2. The first conductive pattern CP1 may be electrically connected to the drain area DRA through a drain connector DRC passing through (e.g., penetrating) one or more insulating layers. The second conductive pattern CP2 may be electrically connected to the source area SRA through a source connector SRC passing through (e.g., penetrating) one or more insulating layers.

As the gate electrode GE and the first and second conductive patterns CP1 and CP2 are connected to other circuit elements and/or lines, the transistor TR_SP1 of the first sub-pixel SP1 may be provided as one of the transistors of the first sub-pixel SP1.

Each of the transistor TR_SP2 of the second sub-pixel SP2 and the transistor TR_SP3 of the third sub-pixel SP3 may be configured in the same or substantially the same manner as that of the transistor TR_SP1 of the first sub-pixel SP1.

As such, the substrate SUB and the pixel circuit layer PCL may include respective circuit elements of the first to third sub-pixels SP1 to SP3.

A via layer VIAL may be disposed on the pixel circuit layer PCL. The via layer VIAL may cover the pixel circuit layer PCL, and may have an overall even (e.g., a flat or substantially flat) surface. The via layer VIAL may planarize or substantially planarize stepped portions on the pixel circuit layer PCL. The via layer VIAL may include at least one of silicon oxide (SiOₓ), silicon nitride (SiNx), and/or silicon carbon nitride (SiCₓN_{y}), but the present disclosure is not limited thereto.

The light-emitting element layer LDL may be disposed on the via layer VIAL. The light-emitting element layer LDL may include first to third reflective electrodes RE1 to RE3, first and second buffer patterns BFP1 and BFP2, first to third cover patterns CVP1 to CVP3, first to third anode electrodes AE1 to AE3, a pixel defining layer PDL, a light-emitting structure EMS, and a cathode electrode CE.

The first to third reflective electrodes RE1 to RE3 may be disposed in the first to third sub-pixels SP1 to SP3, respectively, on the via layer VIAL. Each of the first to third reflective electrodes RE1 to RE3 may contact a corresponding circuit element disposed in the pixel circuit layer PCL through a corresponding via passing through (e.g., penetrating) the via layer VIAL.

The first to third reflective electrodes RE1 to RE3 may reflect light emitted from the light-emitting structure EMS toward the display surface (e.g., the cover window CW). The first to third reflective electrodes RE1 to RE3 may include one or more suitable metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or a suitable alloy of two or more materials selected from among the aforementioned materials, but the present disclosure is not limited thereto.

In some embodiments, a connection electrode may be further provided between each of the first to third reflective electrodes RE1 to RE3 and the vial layer VIAL. The connection electrode may enhance electrical connection characteristics between a corresponding reflective electrode and the corresponding circuit element of the pixel circuit layer PCL. The connection electrode may have a multilayered structure. The multilayered structure may include titanium (Ti), aluminum (Al), titanium nitride (TiN), tantalum nitride (TaN), and/or the like, but the present disclosure is not limited thereto. In some embodiments, a corresponding reflective electrode may be positioned between multiple layers of the connection electrode.

A buffer pattern may be disposed on at least one of the first to third reflective electrodes RE1 to RE3. In some embodiments, the first and second buffer patterns BFP1 and BFP2 may be disposed on the first and third reflective electrodes RE1 and RE3, respectively. Due to the first and second buffer patterns BFP1 and BFP2, heights of the first and third anode electrodes AE1 and AE3 in the third direction DR3 may be adjusted. The first and second buffer patterns BFP1 and BFP2 may include one or more inorganic materials, such as silicon oxide (SiOₓ) and/or silicon nitride (SiNₓ), but the present disclosure is not limited thereto.

The first to third cover patterns CVP1 to CVP3 may be disposed on first to third reflective electrodes RE1 to RE3, respectively. In the first sub-pixel SP1, the first cover pattern CVP1 may be disposed on the first reflective electrode RE1 and the first buffer pattern BFP1. In the second sub-pixel SP2, the second cover pattern CVP2 may be disposed on the second reflective electrode RE2. In the third sub-pixel SP3, the third cover pattern CVP3 may be disposed on the third reflective electrode RE3 and the second buffer pattern BFP2. The first to third cover patterns CVP1 to CVP3 may be formed after the formation of the first and second buffer patterns BFP1 and BFP2 during a manufacturing process. The first to third cover patterns CVP1 through CVP3 may include the same material as that of the first and second buffer patterns BFP1 and BFP2. For example, the first to third cover patterns CVP1 to CVP3 may include one or more inorganic materials, such as silicon oxide (SiOₓ) and/or silicon nitride (SiNₓ), but the present disclosure is not limited thereto.

The first to third anode electrodes AE1 to AE3 are disposed on the first to third cover patterns CVP1 to CVP3, respectively. In some embodiments, the first anode electrode AE1 may cover the first cover pattern CVP1, the first buffer pattern BFP1, and the first reflective electrode RE1. The second anode electrode AE2 may cover the second cover pattern CVP2 and the second reflective electrode RE2. The third anode electrode AE3 may cover the third cover pattern CVP3, the second buffer pattern BFP2, and the third reflective electrode RE3.

The first to third anode electrodes AE1 to AE3 may be electrically connected to the first to third reflective electrodes RE1 to RE3, respectively. For example, each anode electrode may be connected to an end (e.g., an edge) of a corresponding reflective electrode. However, the present disclosure is not limited thereto. To improve electrical connection characteristics between the anode electrodes and the reflective electrodes, the anode electrode may be connected to the reflective electrode in various suitable ways.

In some embodiments, the first to third anode electrodes AE1 to AE3 may include at least one of various suitable transparent conductive materials, such as indium tin oxide (ITO), indium zinc oxide (IZO), zinc oxide (ZnOₓ), indium gallium zinc oxide (IGZO), indium tin zinc oxide (ITZO), and/or indium tin zinc oxide (ITZO). However, the materials of the first to third anode electrodes AE1 to AE3 are not limited thereto. For example, the first to third anode electrodes AE1 to AE3 may include titanium nitride.

The first to third anode electrodes AE1 to AE3 may have the same or substantially the same (or similar) shapes as those of the first to third emission areas EMA1 to EMA3 of FIG. 6 when viewed from the third direction DR3 (e.g., in a plan view).

The first to third anode electrodes AE1 to AE3 and the cathode electrode CE may partially reflect an incident light. The light emitted from the light-emitting layer of the light-emitting structure EMS may be amplified by reciprocating between a corresponding anode electrode and the cathode electrode CE, and may be output through the cathode electrode CE. For example, each anode electrode and the cathode electrode CE may provide a resonant structure in a corresponding sub-pixel. In this case, a distance between each anode electrode and the cathode electrode CE may be understood as a resonance distance for light emitted from the light-emitting layer of a corresponding light-emitting structure EMS.

The first to third sub-pixels SP1 to SP3 may correspond to red, green, and blue colors, respectively. In this case, the height of the first and third anode electrodes AE1 and AE3 in the third direction DR3 may be higher than that of the second anode electrode AE2 by the first and second buffer patterns BFP1 and BFP2. Accordingly, the first and third sub-pixels SP1 and SP3 may have a shorter resonance distance than that of the second sub-pixel SP2 by the first and second buffer patterns BFP1 and BFP2. As such, the resonance distance of each sub-pixel may be adjusted to effectively and efficiently amplify light in a wavelength range of a corresponding color.

In FIG. 7, first and second buffer patterns BFP1 and BFP2 are shown as disposed on the lower portions of the first and third anode electrodes AE1 and AE3, respectively, but the present disclosure is not limited thereto. For example, one of the first and/or second buffer patterns BFP1 and BFP2 may be omitted as needed or desired. As another example, both of the first and second buffer patterns BFP1 and BFP2 may be omitted as needed or desired. In this case, the resonance distance between the anode electrodes and the cathode electrode CE may be equal to each other. As another example, a buffer pattern may be disposed under each of the first to third anode electrodes AE1 to AE3. In this case, buffer patterns disposed under the anode electrodes may have different thicknesses from each other, and accordingly, the resonance distances between the anode electrodes and the cathode electrode CE may be different from each other. As such, by providing a buffer pattern under at least one of the first to third anode electrodes AE1 to AE3 for adjusting a height of a corresponding anode electrode, the resonance distance at each sub-pixel may be optimized.

The pixel defining layer PDL is disposed on a portion of the first to third anode electrodes AE1 to AE3, and on the via layer VIAL. The pixel defining layer PDL has an opening OP overlapping with a portion of each of the first to third anode electrodes AE1 to AE3. The openings OP may define each of the emission areas EMA1 to EMA3. An area overlapping with the pixel defining layer PDL may be understood as a boundary area BDA between neighboring sub-pixels.

The pixel defining layer PDL may include a plurality of sequentially stacked pixel defining layers. Each of the plurality of pixel defining layers may include at least one of silicon oxide (SiOₓ) and/or silicon nitride (SiNₓ). However, the present disclosure is not limited thereto. For example, the pixel defining layer PDL may include an organic insulating layer.

In some embodiments, the pixel defining layer PDL may include first to third pixel defining layers PDL1 to PDL3, and an inorganic insulating layer ISL. The inorganic insulating layer ISL may cover a portion of the first to third anode electrodes AE1 to AE3 and the via layer VIAL. The first pixel defining layer PDL1 may be disposed on the inorganic insulating layer ISL. The second pixel defining layer PDL2 may be disposed on top of the first pixel defining layer PDL1. The third pixel defining layer PDL3 may be disposed between the first pixel defining layer PDL1 and the inorganic insulating layer ISL. In some embodiments, the inorganic insulating layer ISL may be omitted as needed or desired.

The pixel defining layer PDL may include a separator SPR in the boundary area BDA between neighboring sub-pixels. The separator SPR may cause discontinuities, such as a void VD, to form in the light-emitting structure EMS. Due to the discontinuities, at least some of the plurality of layers in the light-emitting structure EMS may be disconnected or warped.

The separator SPR may be formed at the edge of the opening OP, and may have an undercut structure. In other words, the pixel defining layer PDL may have an undercut structure at the edge of the opening OP, and may have a protrusion PJP (e.g., see FIG. 8) at the edge of the opening OP to have an undercut structure. In this case, the protrusion PJP may protrude in a direction toward a center of the opening OP.

In more detail, the second pixel defining layer PDL2 may have a greater width than that of the first pixel defining layer PDL1. As a result, the pixel defining layer PDL may have an undercut structure, because the second pixel defining layer PDL2 includes a protrusion that protrudes from the first pixel defining layer PDL1 toward the center of the opening OP in a plan view. In this case, side surfaces of the first to third pixel defining layers PD1 to PDL3 adjacent to the opening OP may be provided as the separator SPR.

Referring to FIG. 8 in conjunction with FIG. 7, the second pixel defining layer PDL2 may include the protrusions PJP and a flat portion FP. The flat portion FP may fully overlap with the first pixel defining layer PDL1. Each of the protrusions PJP protrudes from the flat portion FP. As such, a width of the second pixel defining layer PDL2 including the protrusions PJP may be larger than a width of the first pixel defining layer PDL1. For example, during a manufacturing process, the first pixel defining layer PDL1 may be undercut so as not to include overlapping portions with each of the protrusions PJP. For example, each of the protrusions PJP of the second pixel defining layer PDL2 may have a shape of eaves on the first pixel defining layer PDL1.

In the boundary area BDA, the third pixel defining layer PDL3 may have a larger width than that of the first pixel defining layer PDL1 and the second pixel defining layer PDL2. However, the present disclosure is not limited thereto, and the third pixel defining layer PDL3 may have a smaller width than that of the second pixel defining layer PDL2.

In the second sub-pixel SP2, the protrusion PJP of the second pixel defining layer PDL2 and a first side surface SSF1 of the first and third pixel defining layers PDL1 and PDL3 may be provided as one separator SPR. Accordingly, a first void VD1 may be formed adjacent to the protrusion PJP of the second pixel defining layer PDL2 in the light-emitting structure EMS. In the third sub-pixel SP3, the protrusion PJP of the second pixel defining layer PDL2 and a second surface SSF2 of the first and third pixel defining layers PDL1 and PDL3 may be provided as another separator SPR. Accordingly, a second void VD2 may be formed adjacent to the protrusion PJP of the second pixel defining layer PDL2 in the light-emitting structure EMS.

Some of the plurality of layers stacked within the light-emitting structure EMS may be disconnected or bent by the first and second voids VD1 and VD2. For example, at least one charge generation layer and at least one hole injection layer included in the light-emitting structure EMS may be disconnected by the first and second voids VD1 and VD2. Thus, due to the separator SPR, portions of the light-emitting structure EMS included in the first to third sub-pixels SP1 to SP3 may be at least partially spaced apart (e.g., separated) from each other.

The pixel defining layer PDL may include additional separators, such that the light-emitting structure EMS further includes discontinuities in the boundary area BDA. In some embodiments, the pixel defining layer PDL may include one or more trenches as a separator in the boundary area BDA. The trenches may penetrate one or more from among first to fourth inorganic insulating layers. Due to the trenches, some of the plurality of layers stacked within the light-emitting structure EMS, such as at least one of the charge generation layer and at least one of the hole injection layer, may be disconnected or bent. In some embodiments, the light-emitting structure EMS may have three light-emitting units that are stacked, each including a light-emitting layer, and two charge generation layers may be disposed between the three light-emitting units. In some embodiments, the pixel defining layer PDL may include one or more trenches in the boundary area BDA.

Referring to FIG. 7, the light-emitting structure EMS may be disposed on the anode electrodes AE exposed by the openings OP of the pixel defining layer PDL. The light-emitting structure EMS may be disposed throughout the first to third sub-pixels SP1 to SP3, filling the openings OP of the pixel defining layer PDL. As described above, the light-emitting structure EMS may be partially disconnected or bent in the boundary area BDA or in an area adjacent to the boundary area BDA by the separator SPR. Accordingly, during an operation of the display panel DP, a current flowing from each of the first to third sub-pixels SP1 to SP3 through the layers included in the light-emitting structure EMS to neighboring sub-pixels may be reduced. Thus, the first to third light-emitting elements LD1 to LD3 may operate with a relatively higher reliability.

In some embodiments, the light-emitting structure EMS may include two light-emitting units stacked sequentially, each of which may include a light-emitting layer to generate light in response to an applied current. In other embodiments, the light-emitting structure EMS may include three light-emitting units stacked sequentially, each of the light-emitting units including a light-emitting layer to generate light in response to an applied current. In some embodiments, a charge generation layer may be disposed between the light-emitting units.

In some embodiments, the light-emitting structure EMS may be formed through a suitable process, such as vacuum deposition, inkjet printing, or the like.

The cathode electrode CE may be disposed on the light-emitting structure EMS. The cathode electrode CE may be provided in common to the first to third sub-pixels SP1 to SP3.

The first anode electrode AE1, a portion of the light-emitting structure EMS overlapping with the first anode electrode AE1, and a portion of the cathode electrode CE overlapping with the first anode electrode AE1 may constitute the first light-emitting element LD1. The second anode electrode AE2, a portion of the light-emitting structure EMS overlapping with the second anode electrode AE2, and a portion of the cathode electrode CE overlapping with the second anode electrode AE2 may constitute the second light-emitting element LD2. The third anode electrode AE3, a portion of the light-emitting structure EMS overlapping with the third anode electrode AE3, and a portion of the cathode electrode CE overlapping with the third anode electrode AE3 may constitute the third light-emitting element LD3.

The encapsulation layer TFE may be disposed on the cathode electrode CE. The encapsulation layer TFE may prevent or substantially prevent oxygen and/or moisture from penetrating into the light-emitting element layer LDL.

An optical functional layer OFL is disposed on the encapsulation layer TFE. In some embodiments, the optical functional layer OFL may be attached to the encapsulation layer TFE via an adhesive layer APL. For example, the optical functional layer OFL may be manufactured separately, and then attached to the encapsulation layer TFE via the adhesive layer APL. The adhesive layer APL may further function to protect the underlying layers, including the encapsulation layer TFE.

The optical functional layer OFL may include a color filter layer CFL and a lens array LA. The color filter layer CFL may include first to third color filters CF1 to CF3 corresponding to the first to third sub-pixels SP1 to SP3, respectively. The first to third color filters CF1 to CF3 may pass light in different wavelength ranges from each other. For example, the first to third color filters CF1 to CF3 may pass light of red, green, and blue colors, respectively.

In some embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA is disposed on the color filter layer CFL. The lens array LA may include first to third lenses LS1 to LS3 corresponding to the first to third sub-pixels SP1 to SP3, respectively. The first to third lenses LS1 to LS3 may output light emitted from the first to third light-emitting elements LD1 to LD3, respectively, in an intended path, thereby improving a light emission efficiency.

An overcoat layer OC may be disposed on the lens array LA. The overcoat layer OC may protect the underlying layers from foreign matter, such as dust, moisture, and the like. The cover window CW may be disposed on the overcoat layer OC.

FIG. 9 is a cross-sectional view illustrating an embodiment of a portion of a light-emitting structure included in any one of the first to third light-emitting elements of FIG. 7.

Referring to FIG. 9, the light-emitting structure may have a tandem structure in which first and second light-emitting units EU1 and EU2 are stacked. The light-emitting structure may be configured the same or substantially the same in each of the first to third light-emitting elements LD1 to LD3 of FIG. 7.

Each of the first and second light-emitting units EU1 and EU2 may include at least one light-emitting layer that generates light in response to an applied current. The first light-emitting unit EU1 may include a first light-emitting layer EML1, a first electron transport unit or layer ETU1, and a first hole transport unit or layer HTU1. The first light-emitting layer EML1 may be disposed between the first electron transport unit ETU1 and the first hole transport unit HTU1. The second light-emitting unit EU2 may include a second light-emitting layer EML2, a second electron transport unit or layer ETU2, and a second hole transport unit or layer HTU2. The second light-emitting layer EML2 may be disposed between the second electron transport unit ETU2 and the second hole transport unit HTU2.

Each of the first and second hole transport units HTU1 and HTU2 may include at least one of a hole injection layer and/or a hole transport layer, and may further include a hole buffer layer, an electron transport layer, and/or the like as necessary or desired. The first and second hole transport units HTU1 and HTU2 may have the same or substantially the same configuration as each other, or may have different configurations from each other.

Each of the first and second electron transport units ETU1 and ETU2 may include at least one of an electron injection layer and/or an electron transport layer, and may further include an electron buffer layer, a hole barrier layer, and the like as necessary or desired. The first and second electron transport units ETU1 and ETU2 may have the same or substantially the same configuration as each other, or may have different configurations from each other.

A connecting layer, which may be provided in the form of a charge generation layer CGL, may be disposed between the first light-emitting unit EU1 and the second light-emitting unit EU2 to connect them to each other. In some embodiments, the charge generation layer CGL may have a stacked structure of a p-dopant layer and an n-dopant layer. For example, the p-dopant layer may include p-type dopants, such as HAT-CN, TCNQ, NDP-9, and/or the like, and the n-dopant layer may include alkali metals, alkaline earth metals, lanthanide-based metals, or suitable combinations thereof. However, the present disclosure is not limited thereto.

In some embodiments, the first light-emitting layer EML1 and the second light-emitting layer EML2 may generate different colors of light from each other. The light emitted from each of the first light-emitting layer EML1 and the second light-emitting layer EML2 may be mixed together and perceived as white light. For example, the first emitting layer EML1 may generate blue-colored light and the second emitting layer EML2 may generate yellow-colored light. In some embodiments, the second light-emitting layer EML2 may include a structure stacked with a first sub light-emitting layer to generate red-colored light and a second sub light-emitting layer to generate green-colored light. The red-colored light and the green-colored light may be mixed together to provide yellow-colored light. In this case, an intermediate layer may be further disposed between the first and second sub light-emitting layers to perform a function of transporting holes and/or a function of preventing the transport of electrons.

In other embodiments, the first light-emitting layer EML1 and the second light-emitting layer EML2 may generate light of the same color as each other.

The light-emitting structure may be formed by a vacuum deposition, an inkjet printing, and/or the like, but the present disclosure is not limited thereto.

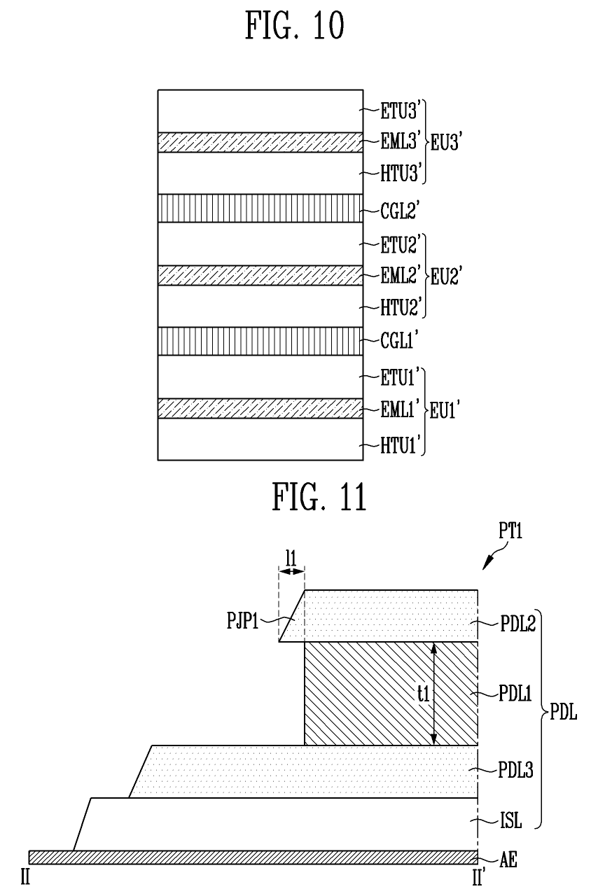

FIG. 10 is a cross-sectional view illustrating an embodiment of a portion of the light-emitting structure included in any one of the first to third light-emitting elements of FIG. 7.

Referring to FIG. 10, the light-emitting structure may have a tandem structure in which first to third light-emitting units EU1' to EU3' are stacked. The light-emitting structure may be configured the same or substantially the same in each of the first to third light-emitting elements LD1 to LD3 of FIG. 7.

Each of the first to third light-emitting units EU1' to EU3' may include a light-emitting layer that generates light in response to an applied current. The first light-emitting unit EU1' may include a first light-emitting layer EML1’, a first electron transport unit or layer ETU1’, and a first hole transport unit or layer HTU1’. The first light-emitting layer EML1’ may be disposed between the first electron transport unit ETU1’ and the first hole transport unit HTU1’. The second light-emitting unit EU2' may include a second light-emitting layer EML2', a second electron transport unit or layer ETU2', and a second hole transport unit or layer HTU2'. The second light-emitting layer EML2’ may be disposed between the second electron transport unit ETU2’ and the second hole transport unit HTU2’. The third light-emitting unit EU3’ may include a third light-emitting layer EML3’, a third electron transport unit or layer ETU3’, and a third hole transport unit or layer HTU3’. The third light-emitting layer EML3’ may be disposed between the third electron transport unit ETU3’ and the third hole transport unit HTU3’.

Each of the first to third hole transport units HTU1’ to HTU3’ may include at least one of a hole injection layer and/or a hole transport layer, and may further include a hole buffer layer, an electron stop layer, and the like as necessary or desired. The first to third hole transport units HTU1’ to HTU3’ may have the same or substantially the same configuration as each other, or different configurations from each other.

Each of the first to third electron transport units ETU1' to ETU3' may include at least one of an electron injection layer and/or an electron transport layer, and may further include an electron buffer layer, a hole barrier layer, and the like as necessary or desired. The first to third electron transport units ETU1' to ETU3' may have the same or substantially the same configuration as each other, or different configurations from each other.

A first charge generation layer CGL1' is disposed between the first light-emitting unit EU1' and the second light-emitting unit EU2'. A second charge generation layer CGL2' is disposed between the second light-emitting unit EU2' and the third light-emitting unit EU3’.

In some embodiments, the first to third light-emitting layers EML1' to EML3' may generate different colors of light from each other. The light emitted from each of the first to third light-emitting layers EML1' through EML3' may be mixed together and perceived as white light. For example, the first light-emitting layer EML1' may generate blue-colored light, the second light-emitting layer EML2' may generate green-colored light, and the third light-emitting layer EML3' may generate red-colored light.

In other embodiments, two or more of the first to third light-emitting layers EML1' to EML3' may generate light of the same color as each other.

Unlike that described above with reference to FIGS. 9 and 10, the light-emitting structure of FIG. 7 or FIG. 8 may include one light-emitting unit in each of the first to third light-emitting elements LD1 to LD3. In this case, the light-emitting units included in the first to third light-emitting elements LD1 to LD3 may emit different colors of light from each other. For example, the light-emitting unit of the first light-emitting element LD1 may emit red-colored light, the light-emitting unit of the second light-emitting element LD2 may emit green-colored light, and the light-emitting unit of the third light-emitting element LD3 may emit blue-colored light. In this case, the light-emitting elements of the first to third sub-pixels SP1 to SP3 may be spaced apart (e.g., separated) from each other, and each of them may be disposed within a corresponding opening OP (e.g., see FIG. 7) of the pixel defining layer PDL. In this case, at least some of the color filters CF1 to CF3 may be omitted.

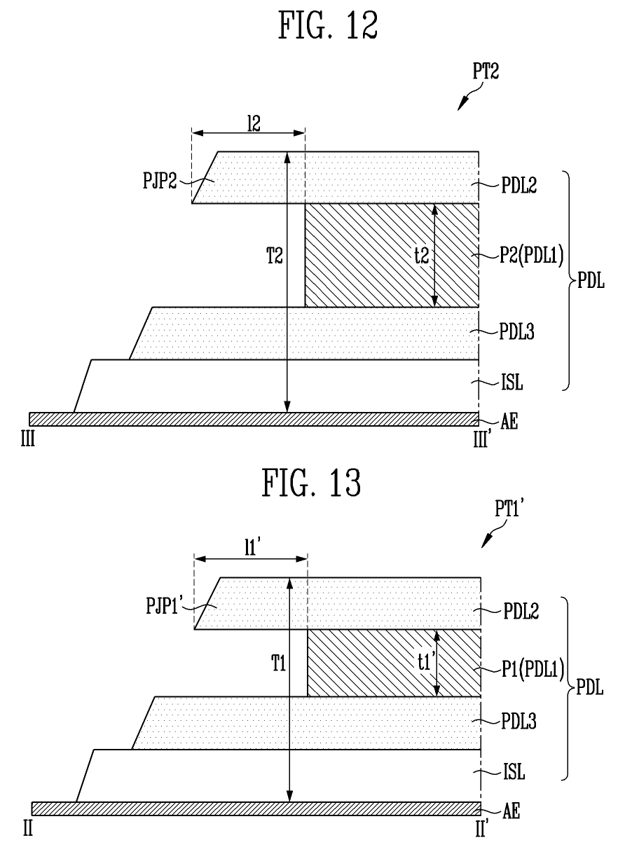

FIG. 11 is a cross-sectional view taken along the line II-II' of FIG. 6. FIG. 12 is a cross-sectional view taken along the line III-III' of FIG. 6. Each of FIGS. 11 and 12 is a diagram showing only an anode electrode AE and a pixel defining layer PDL. The anode electrode AE in each of FIGS. 11 and 12 is one of the first to third anode electrodes AE1 to AE3 of FIG. 7. In the embodiments of FIG. 11 and FIG. 12, a thickness t1 of a first portion of a first pixel defining layer PDL1 and a thickness t2 of a second portion of the first pixel defining layer PDL1 are the same or substantially the same as each other.

Referring to FIGS. 6, 11, and 12, the pixel defining layer PDL may have an undercut structure. In an embodiment, the pixel defining layer PDL may have an undercut structure so that a second pixel defining layer PDL2 includes a protrusion PJP that protrudes from the first pixel defining layer PDL1 toward a center of an opening OP in a plan view.

In the pixel defining layer PDL, a structure of a portion disposed between emission areas EMA (e.g., the first emission areas EMA1) that emit the same color of light as each other and a structure of a portion disposed between the emission areas EMA (e.g., the first emission area EMA1 and the second emission area EMA2, the first emission area EMA1 and the third emission area EMA3, or the second emission area EMA2 and the third emission area EMA3) that emit different colors of light from each other may be different from each other.

In an embodiment, the pixel defining layer PDL may include a first portion PT1 and a second portion PT2 that are adjacent to each other in a plan view and have different structures from each other. In other words, the first portion PT1 may be a portion disposed between emission areas EMA that emit the same color of light as each other in a plan view, and the second portion PT2 may be a portion disposed between emission areas EMA that emit different colors of light from each other in a plan view. The first portion PT1 and the second portion PT2 may be connected to each other and may be formed integrally as each other. In this case, the first portion PT1 of the pixel defining layer PDL may correspond to a first portion PJP1 of the protrusion PJP of the second pixel defining layer PDL2 (e.g., see FIG. 11), and the second portion PT2 of the pixel defining layer PDL may correspond to a second portion PJP2 of the protrusion PJP of the second pixel defining layer PDL2 (e.g., see FIG. 12).

For example, a protruding width l1 of the first portion PJP1 of the protrusions PJP of the pixel defining layer PDL disposed between the emission areas EMA for emitting the same color of light as each other may be different from a protruding width l2 of the second portion PJP2 disposed between the emission areas EMA for emitting different colors of light from each other. In more detail, the protruding width l1 of the first portion PJP1 disposed between the emission areas EMA that emit light of the same color as each other may be smaller than the protruding width l2 of the second portion PJP2 disposed between the emission areas EMA that emit light of different colors from each other. In this case, because the second pixel defining layer PDL2 includes the protrusion PJP protruding from the first pixel defining layer PDL1 in a plan view, a protrusion length l1, from the first pixel defining layer PDL1, of the first portion PJP1 of the second pixel defining layer PDL2 disposed between emission areas EMA for emitting light of the same color as each other may be smaller than a protrusion length l2, from the first pixel defining layer PDL1, of the second portion PJP2 of the second pixel defining layer PDL2 disposed between emission areas EMA for emitting light of different colors from each other. As used herein, the protruding width of the protrusion PJP refers to the same or substantially the same as the protrusion length of the second pixel defining layer PDL2 from the first pixel defining layer PDL1, and the protrusion length (or width) of the second pixel defining layer PDL2 from the first pixel defining layer PDL1 may refer to the length (or width) of the protrusion of the second pixel defining layer PDL2 from the first pixel defining layer PDL1 in a direction toward a center of the opening OP in a plan view.

In an embodiment, the protruding width l1 of the first portion PJP1 of the protrusion PJP may fall within a range of greater than 0 nm and less than about 110 nm. In other words, the protrusion length l1 from the first pixel defining layer PDL1 of the first portion PJP1 of the second pixel defining layer PDL2 may fall within a range of greater than 0 nm and less than about 110 nm. In more detail, the protrusion length l1 from the first pixel defining layer PDL1 of the first portion PJP1 of the second pixel defining layer PDL2 may fall within a range greater than 0 nm and less than about 90 nm. In more detail, the protrusion length l1 from the first pixel defining layer PDL1 of the first portion PJP1 of the second pixel defining layer PDL2 may fall within a range greater than 0 nm and less than about 45 nm. However, the present disclosure is not limited thereto.

In a case that the protrusion length l1 of the first portion PJP1 of the second pixel defining layer PDL2 from the first pixel defining layer PDL1 is about 110 nm or more, the cathode electrode CE disposed on the first portion PJP1 may be disconnected. In this case, because the second portion PJP2 protrudes further in the direction of the center of the opening OP than the first portion PJP1, the protrusion length l2 of the second portion PJP2 of the second pixel defining layer PDL2 from the first pixel defining layer PDL1 is also about 110 nm or more. Accordingly, the cathode electrode CE disposed on the second portion PJP2 may also be disconnected. In other words, the cathode electrode CE may not be connected as a whole within the display area DA, and a floating portion may be formed. Because the floating portion of the cathode electrode CE does not receive a current or a signal through the cathode electrode CE, the light-emitting structure EMS corresponding to the floating portion may not emit light. Accordingly, the protrusion length l1 of the first portion PJP1 of the second pixel defining layer PDL2 from the first pixel defining layer PDL1 may be greater than 0 nm and less than about 110 nm. Accordingly, the cathode electrode CE may be connected throughout the display area DA.

In an embodiment, the protruding width l2 of the second portion PJP2 of the protrusion PJP may fall within a range of greater than or equal about 35 nm and less than or equal about 250 nm. In other words, the protrusion length l2 of the second portion PJP2 of the second pixel defining layer PDL2 from the first pixel defining layer PDL1 may fall within a range of greater than or equal about 35 nm and less than or equal about 250 nm. In more detail, the protrusion length l2 of the second portion PJP2 of the second pixel defining layer PDL2 from the first pixel defining layer PDL1 may fall within a range of greater than or equal about 45 nm and less than or equal about 200 nm. In more detail, the protrusion length l2 of the second portion PJP2 of the second pixel defining layer PDL2 from the first pixel defining layer PDL1 may fall within a range of greater than or equal about 45 nm and less than or equal about 90 nm. However, the present disclosure is not limited thereto.

In a case that the protrusion length l2 of the second portion PJP2 of the second pixel defining layer PDL2 from the first pixel defining layer PDL1 is less than about 35 nm, a portion of the light-emitting structure EMS disposed on the second portion PJP2 may not be disconnected. In more detail, in a case that the protrusion length l2 of the second portion PJP2 of the second pixel defining layer PDL2 from the first pixel defining layer PDL1 is less than about 35 nm, the charge generation layer CGL disposed on the second portion PJP2 may not be disconnected. In this case, a current may flow through the charge generation layer CGL of the light-emitting structure EMS to neighboring sub-pixels. A current leakage to neighboring sub-pixels may cause color mixing, and may degrade a display quality. Furthermore, in a case that the protrusion length l2 of the second portion PJP2 of the second pixel defining layer PDL2 from the first pixel defining layer PDL1 is greater than about 250 nm, it may be difficult to form an undercut structure in a process, and the area of the opening OP may become excessively small, resulting in a decrease in the emission area EMA and a decrease in the light emission efficiency. Accordingly, the protrusion length l2 of the second portion PJP2 of the second pixel defining layer PDL2 from the first pixel defining layer PDL1 according to an embodiment may be in a range from about 35 nm or more to about 250 nm or less. Accordingly, the charge generation layer CGL disposed on the emission areas EMA for emitting different colors of light from each other may be disconnected. As the protrusion length of the second pixel defining layer PDL2 increases, a portion of the light-emitting structure EMS disposed on the pixel defining layer PDL may be easily disconnected due to the separator SPR of the undercut structure (e.g., see FIGS. 7 and 8). Therefore, a portion of the light-emitting structure EMS disposed on the second portion PJP2 having a larger protrusion length may be more prone to breakage than the first portion PJP1 having a smaller protrusion length. In other words, by configuring the structure of the pixel defining layer PDL disposed between the emission areas EMA that emit light of the same color as each other differently from the structure of the pixel defining layer PDL disposed between the emission areas EMA that emit light of different colors from each other, the cathode electrode CE may not be disconnected between the emission areas EMA that emit light of the same color as each other (e.g., the first portion PT1 in FIG. 11), and the charge generation layer CGL (e.g., see FIG. 9) may be disconnected between emission areas EMA for emitting different colors of light from each other (e.g., the second portion PT2 in FIG. 12). Accordingly, the cathode electrode CE may be connected as a whole without a floating portion on the display area DA through the area overlapping with the first portion PT1, and the charge generation layer CGL may be disconnected in the area overlapping with the second portion PT2, such that the current leaking to neighboring sub-pixels may be reduced, thereby preventing or substantially preventing color mixing. Thus, the reliability of the display device may be improved.

FIG. 13 is a cross-sectional view taken along the line II-II' of FIG. 6. FIG. 13 may illustrate another embodiment of FIG. 11. FIG. 13 is a cross-sectional view illustrating only an anode electrode AE and a pixel defining layer PDL. In the embodiment of FIG. 13, unlike the embodiment of FIG. 11, a first portion PJP1’ of the second pixel defining layer PDL2 may be connected to the second portion PJP2 of the second pixel defining layer PDL2 without a step in a plane (e.g., a protrusion length l1’ of the first portion PJP1’ of the second pixel defining layer PDL2 is the same or substantially the same as the protrusion length l2 of the second portion PJP2 of the second pixel defining layer PDL2), and a thickness t1’ of a first portion P1 of the first pixel defining layer PDL1 of FIG. 13 may be smaller than the thickness t1 of the first pixel defining layer PDL1 of FIG. 11.

Referring to FIGS. 6, 12, and 13, in the pixel defining layer PDL, a structure of a portion disposed between emission areas EMA that emit light of the same color as each other (e.g., the first emission areas EMA1) and a structure of a portion disposed between the emission areas EMA (e.g., the first emission area EMA1 and the second emission area EMA2, the first emission area EMA1 and the third emission area EMA3, or the second emission area EMA2 and the third emission area EMA3) that emit different colors of light from each other may be different from each other.

In an embodiment, the pixel defining layer PDL may include a first portion PT1’ and a second portion PT2 that are adjacent to each other in a plan view, and have different structures from each other. The first portion PT1' may be a portion disposed between emission areas EMA that emit light of the same color as each other, and the second portion PT2 may be a portion disposed between emission areas EMA that emit light of different colors from each other. The first portion PT1’ and the second portion PT2 may be connected to each other and may be formed integrally with each other. In this case, the first portion PT1’ of the pixel defining layer PDL may correspond to the first portion P1 of the first pixel defining layer PDL1 (e.g., see FIG. 13), and the second portion PT2 of the pixel defining layer PDL may correspond to the second portion P2 of the first pixel defining layer PDL1 (e.g., see FIG. 12).

For example, a thickness T1 of the first portion PT1’ disposed between the emission areas EMA for emitting the same color of light as each other may be different from a thickness T2 of the second portion PT2 disposed between the emission areas EMA for emitting different colors of light from each other. In more detail, the thickness T1 of the first portion PT1' disposed between the emission areas EMA for emitting light of the same color as each other may be smaller than the thickness T2 of the second portion PT2 disposed between the emission areas EMA for emitting light of different colors from each other. As used herein, the thickness of the pixel defining layer PDL (e.g., the thickness T1 of the first portion PT1’ and the thickness T2 of the second portion PT2) may refer to a straight-line distance in a direction orthogonal to an upper surface of the anode electrode AE from the upper surface of the anode electrode AE to an upper surface of the pixel defining layer PDL.

In an embodiment, the thickness T1 of the first portion PT1' may be in a range of greater than 0 nm to less than about 400 nm. In more detail, the thickness T1 of the first portion PT1' may be in the range of greater than 0 nm to less than about 322.5 nm. In more detail, the thickness T1 of the first portion PT1' may be in the range of greater than 0 nm to less than about 317.5 nm. However, the present disclosure is not limited thereto.

In a case that the thickness T1 of the first portion PT1' is about 400 nm or more, the cathode electrode CE disposed on the first portion PT1' may be disconnected. In this case, because the thickness T2 of the second portion PT2 is larger than the thickness T1 of the first portion PT1’, the thickness T2 of the second portion PT2 is also larger than about 400 nm. Accordingly, the cathode electrode CE disposed on the second portion PT2 may also be disconnected. In other words, the cathode electrode CE may not be connected as a whole within the display area DA, and a floating portion may be formed. Because the floating portion of the cathode electrode CE does not receive any current or signal through the cathode electrode CE, the light-emitting structure EMS corresponding to the floating portion may not emit light. Therefore, the thickness T1 of the first portion PT1’ may be greater than 0 nm and less than about 400 nm. Accordingly, the cathode electrode CE may be connected as a whole within the display area DA.

In an embodiment, the thickness T2 of the second portion PT2 may be in a range of about 250 nm or more to about 420 nm or less. In more detail, the thickness T2 of the second portion PT2 may be in the range of about 317.5 nm or more to about 350 nm or less. In more detail, the thickness T2 of the second portion PT2 may be in the range of about 317.5 nm or more to about 322.5 nm or less. However, the present disclosure is not limited thereto.

In a case that the thickness T2 of the second portion PT2 is less than about 250 nm, a portion of the light-emitting structure EMS disposed on the second portion PT2 may not be disconnected. In more detail, in a case that the thickness T2 of the second portion PT2 is less than about 250 nm, the charge generation layer CGL disposed on the second portion PT2 may not be disconnected. In this case, a current may flow through the charge generation layer CGL of the light-emitting structure EMS to neighboring sub-pixels. A leaked current to neighboring sub-pixels may cause color mixing, and may degrade a display quality. Furthermore, in a case that the thickness T2 of the second portion PT2 is greater than about 420 nm, the light-emitting structure EMS disposed on the second portion PT2 may be disconnected as a whole. In other words, all layers of the light-emitting structure EMS, not just the charge generation layer CGL, may be disconnected on the second portion PT2. Accordingly, the thickness T2 of the second portion PT2 may be in a range from about 250 nm or more to about 420 nm or less. Accordingly, the charge generation layer CGL disposed on the emission areas EMA for emitting different colors of light from each other may be disconnected without disconnecting the light-emitting structure EMS as a whole.

In more detail, a thickness t1’ of the first portion P1 of the first pixel defining layer PDL1 disposed between the emission areas EMA for emitting light of the same color as each other may be smaller than a thickness t2 of the second portion P2 disposed between the emission areas EMA for emitting light of different colors from each other.

As the thickness t2 of the first pixel defining layer PDL1 increases, a portion of the light-emitting structure EMS disposed on the pixel defining layer PDL may be easily disconnected due to the separator SPR (e.g., see FIG. 7) of the undercut structure. Therefore, a portion of the light-emitting structure EMS disposed on the second portion P2 having a larger thickness t2 may be more prone to breakage than the first portion P1 having a smaller thickness t1’. In other words, by configuring the structure of the pixel defining layer PDL disposed between the emission areas EMA that emit light of the same color as each other differently from the structure of the pixel defining layer PDL disposed between the emission areas EMA that emit light of different colors from each other, the cathode electrode CE may not be disconnected between the emission areas EMA for emitting light of the same color as each other (e.g., the first portion PT1’ of FIG. 13), and the charge generation layer CGL may be disconnected between the emission areas EMA for emitting light of different colors from each other (e.g., the second portion PT2 of FIG. 12).

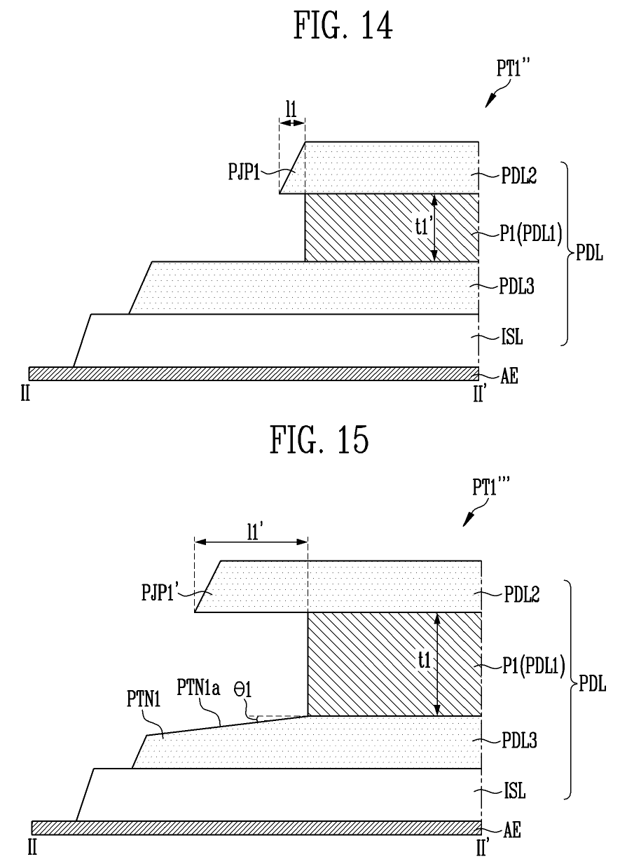

FIG. 14 is a cross-sectional view taken along the line II-II' of FIG. 6. FIG. 14 may illustrate another embodiment of FIG. 11. FIG. 14 is a cross-sectional view illustrating only an anode electrode AE and a pixel defining layer PDL. In the embodiment of FIG. 14, a protrusion length l1 is equal to or substantially equal to the protrusion length l1 of the first portion PJP1 of the second pixel defining layer PDL2 of FIG. 11, and a thickness t1’ is equal to or substantially equal to the thickness t1’ of the first portion P1 of the first pixel defining layer PDL1 of FIG. 13.

Referring to FIGS. 6, 12, and 14, in the pixel defining layer PDL, a structure of a portion disposed between emission areas EMA that emit light of the same color as each other (e.g., the first emission areas EMA1) and a structure of a portion disposed between the emission areas EMA (e.g., the first emission area EMA1 and the second emission area EMA2, the first emission area EMA1 and the third emission area EMA3, or the second emission area EMA2 and the third emission area EMA3) that emit different colors of light from each other may be different from each other.

In an embodiment, the pixel defining layer PDL may include a first portion PT1’’ and a second portion PT2 that are adjacent to each other in a plan view and have different structures from each other. The first portion PT1'' may be a portion disposed between emission areas EMA that emit light of the same color as each other, and the second portion PT2 may be a portion disposed between emission areas EMA that emit light of different colors from each other. The first portion PT1’’ and the second portion PT2 may be connected to each other and may be formed integrally with each other. In this case, the first portion PT1’’ of the pixel defining layer PDL may correspond to the first portion PJP1 of the protrusion PJP of the second pixel defining layer PDL2 (e.g., see FIG. 14), and the second portion PT2 of the pixel defining layer PDL may correspond to the second portion PJP2 of the protrusion PJP of the second pixel defining layer PDL2 (e.g., see FIG. 12). Further, the first portion PT1’’ of the pixel defining layer PDL may correspond to the first portion P1 of the first pixel defining layer PDL1 (e.g., see FIG. 14), and the second portion PT2 of the pixel defining layer PDL may correspond to the second portion P2 of the first pixel defining layer PDL1 (e.g., see FIG. 12).

For example, a protruding width l1 of a first portion PJP1 of the protrusions PJP of the pixel defining layer PDL disposed between emission areas EMA that emit light of the same color as each other may be different from a protruding width l2 of a second portion PJP2 disposed between emission areas EMA that emit light of different colors from each other. In more detail, the protruding width l1 of the first portion PJP1 of the protrusions PJP of the pixel defining layer PDL disposed between the emission areas EMA that emit the same color as each other of light may be smaller than the protruding width l2 of the second portion PJP2 disposed between the emission areas EMA that emit different colors of light from each other. In other words, the protrusion length l1, from the first pixel defining layer PDL1, of the first portion PJP1 of the second pixel defining layer PDL2 disposed between the emission areas EMA for emitting light of the same color as each other may be smaller than the protrusion length l2, from the first pixel defining layer PDL1, of the second portion PJP2 of the second pixel defining layer PDL2 disposed between the emission areas EMA for emitting light of different colors from each other.

Further, a thickness t1’ of the first portion P1 of the first pixel defining layer PDL1 disposed between the emission areas EMA for emitting light of the same color as each other may be smaller than a thickness t2 of the second portion P2 disposed between the emission areas EMA for emitting light of different colors from each other.

As the protrusion length l2 of the second pixel defining layer PDL2 increases and the thickness T2 of the pixel defining layer PDL increases, a portion of the light-emitting structure EMS disposed on the pixel defining layer PDL may be easily disconnected due to the separator SPR (e.g., see FIG. 7) of the undercut structure. Therefore, a portion of the light-emitting structure EMS disposed on the second portion PT2 having a larger protrusion length l2 and a larger thickness t2 may be more prone to breakage than the first portion PT1’’ having a smaller protrusion length l1 and a smaller thickness t1’. In other words, by configuring the structure of the pixel defining layer PDL disposed between the emission areas EMA that emit light of the same color as each other differently from the structure of the pixel defining layer PDL disposed between the emission areas EMA that emit light of different colors from each other, the cathode electrode CE may not be disconnected between the emission areas EMA for emitting light of the same color as each other (e.g., the first portion PT1’’ of FIG. 14), and the charge generation layer CGL may be disconnected between the emission areas EMA for emitting light of different colors from each other (e.g., the second portion PT2 of FIG. 12).

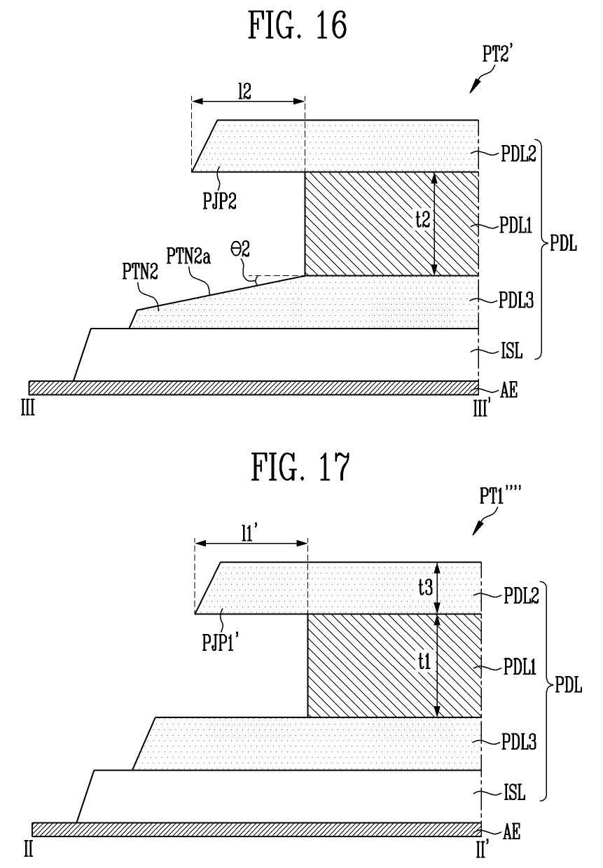

FIG. 15 is a cross-sectional view taken along the line II-II' of FIG. 6. FIG. 15 may illustrate another embodiment of FIG. 11. FIG. 16 is a cross-sectional view taken along the line III-III' of FIG. 6. FIG. 6 may illustrate another embodiment of FIG. 12. Each of FIGS. 15 and 16 is a diagram illustrating only an anode electrode AE and a pixel defining layer PDL. A first portion PT1’’’ of the pixel defining layer PDL of FIG. 15 may be the same or substantially the same structure as that of the second portion PT2 of the pixel defining layer PDL of FIG. 12, except for a third pixel defining layer PDL3 may be different. A second portion PT2’ of the pixel defining layer PDL of FIG. 16 may be the same or substantially the same structure as that of the second portion PT2 of the pixel defining layer PDL of FIG. 12, except for a third pixel defining layer PDL3 may be different.

Referring to FIGS. 6, 15, and 16, in the pixel defining layer PDL, a structure of a portion disposed between emission areas EMA that emit light of the same color as each other (e.g., the first emission areas EMA1) and a structure of a portion disposed between the emission areas EMA (e.g., the first emission area EMA1 and the second emission area EMA2, the first emission area EMA1 and the third emission area EMA3, or the second emission area EMA2 and the third emission area EMA3) that emit different colors of light from each other may be different from each other.

In an embodiment, the pixel defining layer PDL may include a first portion PT1’’’ and a second portion PT2' that are adjacent to each other in a plan view and have different structures from each other. The first portion PT1’’’ may be a portion disposed between emission areas EMA that emit light of the same color as each other, and the second portion PT2’ may be a portion disposed between emission areas EMA that emit light of different colors from each other. The first portion PT1’’’ and the second portion PT2’ may be connected to each other and may be formed integrally with each other. In this case, the first portion PT1’’’ of the pixel defining layer PDL may correspond to a first portion PTN1 of the third pixel defining layer PDL3 (e.g., see FIG. 15), and the second portion PT2’ of the pixel defining layer PDL may correspond to a second portion PTN2 of the third pixel defining layer PDL3 (e.g., see FIG. 16).

For example, a slope θ1 of a side surface PTN1a of the first portion PTN1 of the third pixel defining layer PDL3 disposed between emission areas EMA for emitting light of the same color as each other may be different from a slope θ2 of a side surface PTN2a of the second portion PTN2 of the third pixel defining layer PDL3 disposed between emission areas EMA for emitting light of different colors from each other. In more detail, the slope θ1 of the side surface PTN1a of the first portion PTN1 of the third pixel defining layer PDL3 disposed between the emission areas EMA for emitting the same color of light as each other may be smaller than the slope θ2 of the side surface PTN2a of the second portion PTN2 of the third pixel defining layer PDL3 disposed between the emission areas EMA for emitting different colors of light from each other. In other words, the side surface PTN1a of the first portion PTN1 of the third pixel defining layer PDL3 disposed between the emission areas EMA for emitting light of the same color as each other may be flatter than the side surface PTN2a of the second portion PTN2 of the third pixel defining layer PDL3 disposed between the emission areas EMA for emitting light of different colors from each other.

As the slope θ2 of the third pixel defining layer PDL3 increases, a portion of the light-emitting structure EMS disposed on the pixel defining layer PDL may be easily disconnected due to the separator SPR (e.g., see FIG. 7) of the undercut structure. Therefore, a portion of the light-emitting structure EMS disposed on the second portion PTN2 having a larger slope θ2 may be more prone to breakage than the first portion PTN1 having a smaller slope θ1. In other words, by configuring the structure of the pixel defining layer PDL disposed between the emission areas EMA that emit light of the same color as each other differently from the structure of the pixel defining layer PDL disposed between the emission areas EMA that emit light of different colors from each other, the cathode electrode CE may not be disconnected between the emission areas EMA for emitting light of the same color as each other (e.g., the first portion PT1’’’ of FIG. 15), and the charge generation layer CGL may be disconnected between the emission areas EMA for emitting light of different colors from each other (e.g., the second portion PT2’ of FIG. 16).

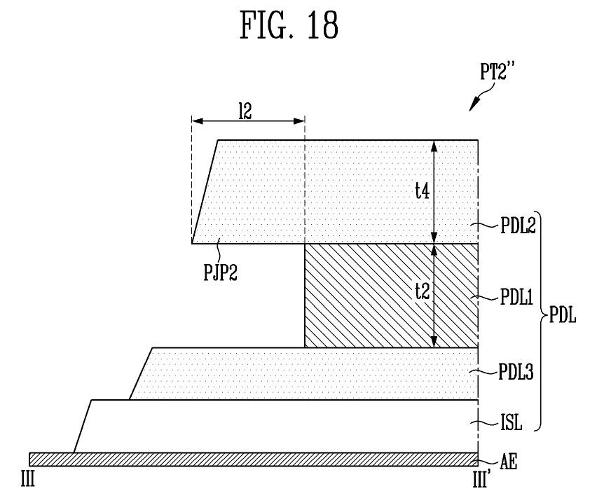

FIG. 17 is a cross-sectional view taken along the line II-II' of FIG. 6. FIG. 17 may illustrate another embodiment of FIG. 11. FIG. 18 is a cross-sectional view taken along the line III-III' of FIG. 6. FIG. 18 may illustrate another embodiment of FIG. 12. Each of FIGS. 17 and 18 is a diagram illustrating only an anode electrode AE and a pixel defining layer PDL. A first portion PT1’’’’ of the pixel defining layer PDL of FIG. 17 may be the same or substantially the same structure as that of the second portion PT2 of the pixel defining layer PDL of FIG. 12. A second portion PT2’’ of the pixel defining layer PDL of FIG. 18 may be the same or substantially the same structure as that of the second portion PT2 of the pixel defining layer PDL of FIG. 12, except for a second pixel defining layer PDL2 may be different.

Referring to FIGS. 6, 17, and 18, in the pixel defining layer PDL, a structure of a portion disposed between emission areas EMA that emit light of the same color as each other (e.g., the first emission areas EMA1) and a structure of a portion disposed between the emission areas EMA (e.g., the first emission area EMA1 and the second emission area EMA2, the first emission area EMA1 and the third emission area EMA3, or the second emission area EMA2 and the third emission area EMA3) that emit different colors of light from each other may be different from each other.

In an embodiment, the pixel defining layer PDL may include a first portion PT1’’’’ and a second portion PT2’’ that are adjacent to each other in a plan view and have different structures from each other. The first portion PT1’’’’ may be a portion disposed between emission areas EMA that emit light of the same color as each other, and the second portion PT2’’ may be a portion disposed between emission areas EMA that emit light of different colors from each other. The first portion PT1’’’’ and the second portion PT2’’ may be connected to each other and may be formed integrally with each other.

For example, a thickness of the first portion PT1’’’’ disposed between the emission areas EMA for emitting light of the same color as each other may be different from a thickness of the second portion PT2’’ disposed between the emission areas EMA for emitting light of different colors from each other. In more detail, a thickness t3 of a portion corresponding to the first portion PT1’’’’ of the second pixel defining layer PDL2 disposed between the emission areas EMA for emitting light of the same color as each other may be smaller than a thickness t4 of a portion corresponding to the second portion PT2’’ of the second pixel defining layer PDL2 disposed between the emission areas EMA for emitting light of different colors from each other.

As the thickness t4 of the second portion PT2’’ of the second pixel defining layer PDL2 increases, a thickness of the second portion PT2’’ of the pixel defining layer PDL may increase. In other words, as the thickness of the pixel defining layer PDL increases, a portion of the light-emitting structure EMS disposed on the pixel defining layer PDL may be easily disconnected due to the separator SPR (e.g., see FIG. 7) of the undercut structure. Therefore, a portion of the light-emitting structure EMS disposed on the second portion PT2’’ having a larger thickness t4 of the second pixel defining layer PDL2 may be more prone to breakage than the first portion PT1’’’’ having a smaller thickness t3 of the second pixel defining layer PDL2. In other words, by configuring the structure of the pixel defining layer PDL disposed between the emission areas EMA for emitting light of the same color as each other differently from the structure of the pixel defining layer PDL disposed between the emission areas EMA for emitting light of different colors from each other, the cathode electrode CE may not be disconnected between the emission areas EMA for emitting light of the same color as each other (e.g., the first portion PT1'''' of FIG. 17), and the charge generation layer CGL may be disconnected between the emission areas EMA for emitting light of different colors from each other (e.g., the second portion PT2'' of FIG. 18).

FIGS. 11 through 18 are example drawings, and the present disclosure is not limited thereto. For example, the first portion of the pixel defining layer PDL according to an embodiment may have structures of the first pixel defining layer PDL1 and the second pixel defining layer PDL2 according to FIG. 14, and the third pixel defining layer PDL3 according to FIG. 15.

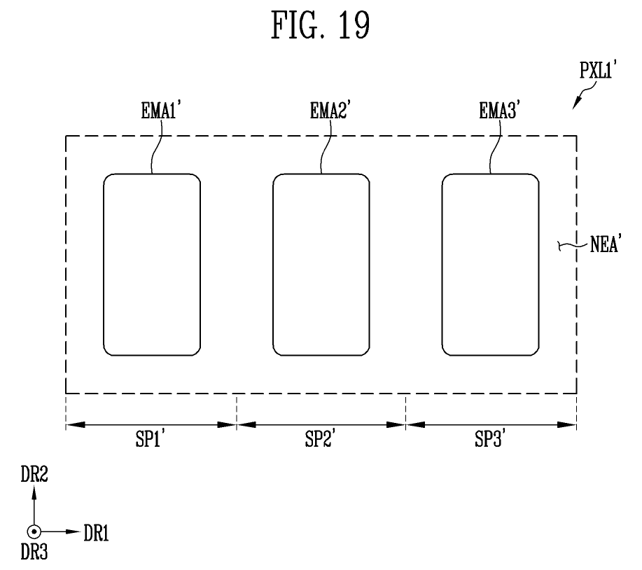

FIG. 19 is a plan view illustrating an arrangement of the pixels of FIG. 6 according to an embodiment.

Referring to FIG. 19, a first pixel PXL1' may include first to third sub-pixels SP1' to SP3' arranged along the first direction DR1.

The first sub-pixel SP1’ may include a first emission area EMA1’, and a non-emission area NEA’ around the first emission area EMA1’. The second sub-pixel SP2’ may include a second emission area EMA2’, and the non-emission area NEA’ around the second emission area EMA2’. The third sub-pixel SP3’ may include a third emission area EMA3’, and the non-emission area NEA’ around the third emission area EMA3’.

The first emission area EMA1’ may be an area where light is emitted from a portion of the light-emitting structure EMS (e.g., see FIG. 7) corresponding to the first sub-pixel SP1’. The second emission area EMA2’ may be an area where light is emitted from a portion of the light-emitting structure EMS corresponding to the second sub-pixel SP2’. The third emission area EMA3’ may be an area where light is emitted from a portion of the light-emitting structure EMS corresponding to the third sub-pixel SP3’.

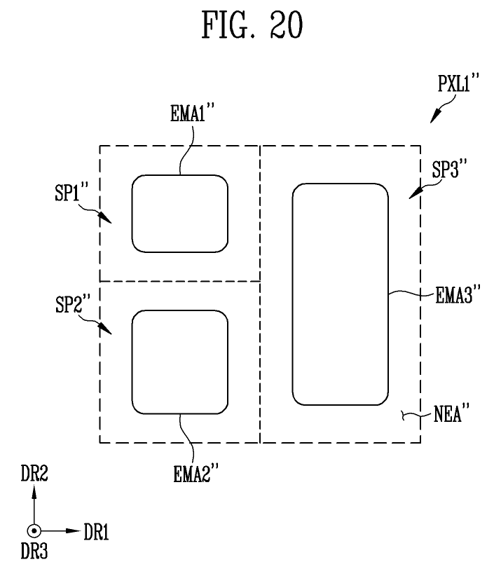

FIG. 20 is a plan view illustrating an arrangement of the pixels of FIG. 6 according to an embodiment.

Referring to FIG. 20, the first pixel PXL1'' may include first to third sub-pixels SP1'' to SP3''.

The first sub-pixel SP1'' may include a first emission area EMA1'', and a non-emission area NEA’’ around the first emission area EMA1''. The second sub-pixel SP2'' may include a second emission area EMA2'', and the non-emission area NEA’’ around the second emission area EMA2''. The third sub-pixel SP3'' may include a third emission area EMA3'', and the non-emission area NEA’’ around the third emission area EMA3''.

The first sub-pixel SP1'' and the second sub-pixel SP2'' may be arranged along the second direction DR2. The third sub-pixel SP3'' may be disposed in the first direction DR1 from each of the first and second sub-pixels SP1'' and SP2''.

The second sub-pixel SP2'' may have a larger area than that of the first sub-pixel SP1'', and the third sub-pixel SP3'' may have a larger area than that of the second sub-pixel SP2''. Accordingly, the second emission area EMA2'' may have a larger area than that of the first emission area EMA1'', and the third emission area EMA3'' may have a larger area than that of the second emission area EMA2''. However, the present disclosure is not limited thereto. For example, the first and second sub-pixels SP1'' and SP2'' may have the same or substantially the same area as each other, and the third sub-pixel SP3'' may have a larger area than that of each of the first and second sub-pixels SP1'' and SP2''. As such, the areas of the first to third sub-pixels SP1'' to SP3'' may be variously modified as needed or desired.

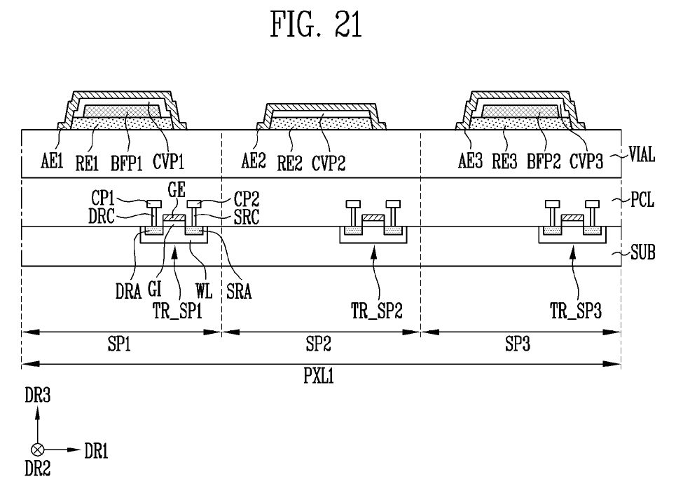

FIGS. 21 through 37 illustrate a method of manufacturing a display device according to an embodiment. FIGS. 21 to 37 may illustrate a method of manufacturing the display device according to the embodiment illustrated in FIG. 7. Accordingly, redundant description may be simplified, or may not be repeated hereinafter.

Referring to FIG. 21, a pixel circuit layer PCL may be formed on the substrate SUB. A via layer VIAL may be formed on the pixel circuit layer PCL.

On the via layer VIAL, first to third reflective electrodes RE1 to RE3 may be formed in the first to third sub-pixels SP1 to SP3, respectively. Buffer patterns BFP1 and BFP2 may be formed on at least one of the first to third reflective electrodes RE1 to RE3. For example, first and second buffer patterns BFP1 and BFP2 may be disposed on the first and third reflective electrodes RE1 and RE3, respectively. First and third cover patterns CVP1 to CVP3 may be formed on the first and third reflective electrodes RE1 to RE3, respectively. In the first sub-pixel SP1, the first cover pattern CVP1 may be formed on the first reflective electrode RE1 and the first buffer pattern BFP1. In the second sub-pixel SP2, the second cover pattern CVP2 may be formed on the second reflective electrode RE2. In the third sub-pixel SP3, the third cover pattern CVP3 may be formed on the third reflective electrode RE3 and the second buffer pattern BFP2.

First to third anode electrodes AE1 to AE3 may be formed on the first to third cover patterns CVP1 to CVP3, respectively.

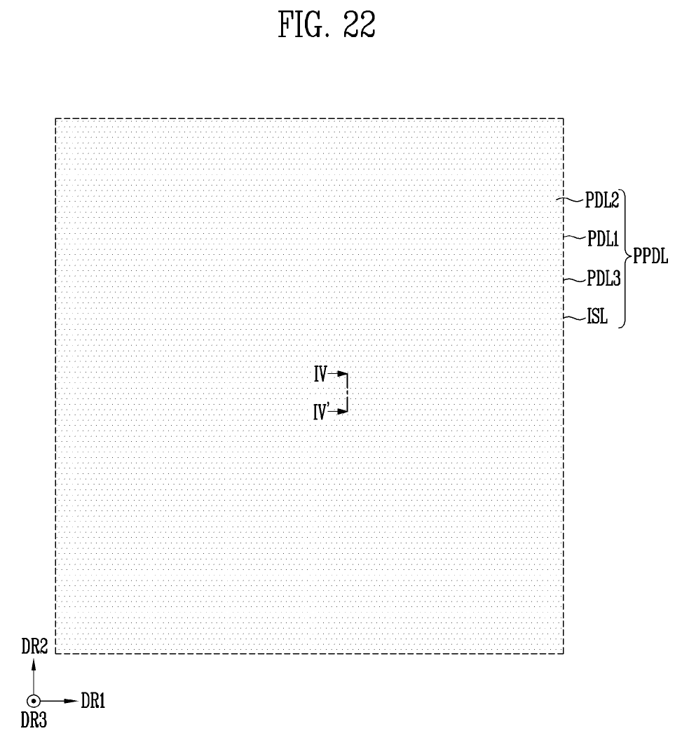

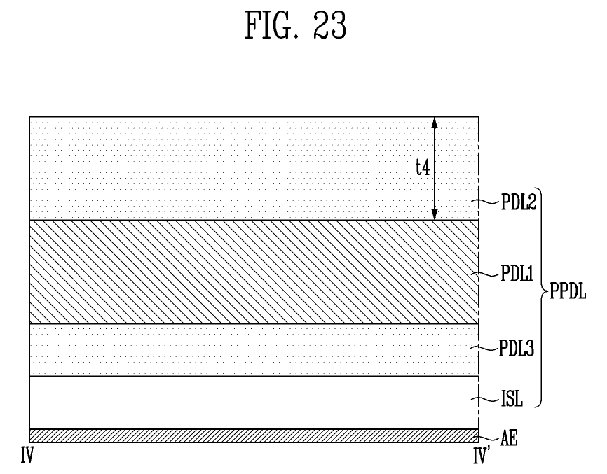

FIG. 23 is a cross-sectional view taken along the line IV-IV' of FIG. 22. In FIG. 23, only an anode electrode AE and a preliminary pixel defining layer PPDL may be shown.

Referring further to FIGS. 22 and 23, the preliminary pixel defining layer PPDL may be formed on the first to third anode electrodes AE1 to AE3 as a whole.

In more detail, an inorganic insulating layer ISL may be formed on the first to third anode electrodes AE1 to AE3. A third pixel defining layer PDL3 may be formed on the inorganic insulating layer ISL. A first pixel defining layer PDL1 may be formed on the third pixel defining layer PDL3. A second pixel defining layer PDL2 may be formed on the first pixel defining layer PDL1. The second pixel defining layer PDL2 may be formed with a suitable thickness (e.g., a preset or predetermined thickness) t4.

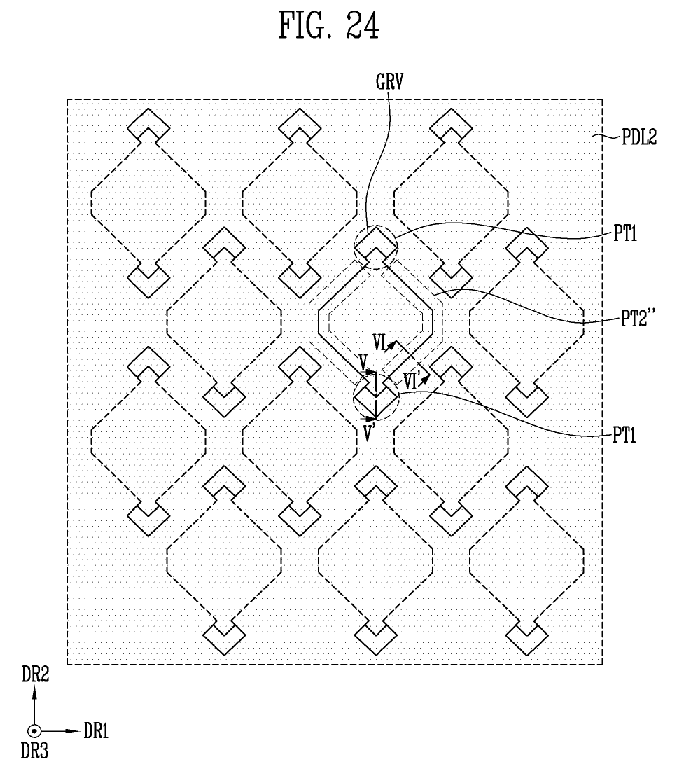

Referring further to FIG. 24, the preliminary pixel defining layer PPDL may include a first portion PT1 and a second portion PT2’’ adjacent to each other in a plan view, and formed with different structures from each other. The first portion PT1 may be disposed between emission areas EMA that emit light of the same color as each other, and the second portion PT2'' may be disposed between emission areas EMA that emit light of different colors from each other.

The portion corresponding to the first portion PT1 of the second pixel defining layer PDL2 may be partially etched. In more detail, except for a portion of the first portion PT1 of the second pixel defining layer PDL2 that is etched later to form an opening, a portion adjacent to the portion to be etched later may be partially etched and a groove GRV may be formed in a corresponding portion.

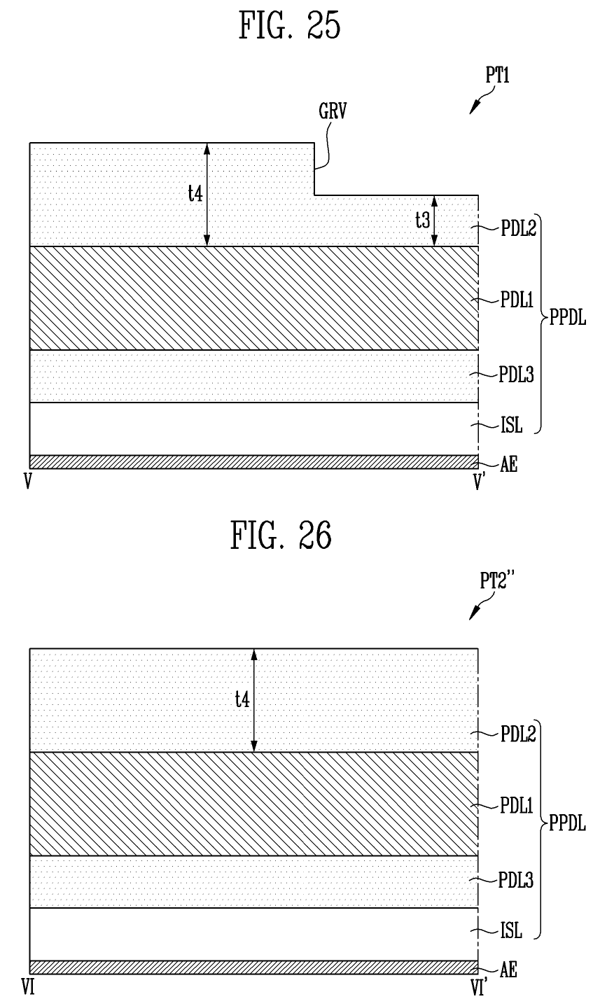

FIG. 25 is a cross-sectional view taken along the line V-V' of FIG. 24. FIG. 26 is a cross-sectional view taken along the line VI-VI' of FIG. 24. For example, FIG. 25 is a cross-sectional view including a portion corresponding to the first portion PT1 of the preliminary pixel defining layer PPDL, and FIG. 26 is a cross-sectional view including a portion corresponding to the second portion PT2’’ of the preliminary pixel defining layer PPDL.

Referring further to FIGS. 25 and 26, a portion of the first portion PT1 of the second pixel defining layer PDL2 may be partially etched to form the groove GRV. As the groove GRV is formed, a thickness t3 of the second pixel defining layer PDL2 overlapping with the groove GRV may be smaller than a thickness t4 of the second pixel defining layer PDL2 without the groove GRV formed therein.

The second portion PT2'' of the second pixel defining layer PDL2 may not be etched, and may maintain the thickness t4.

In an embodiment, a thickness of the first portion PT1, in which a portion of the first portion PT1 is partially etched to form the groove GRV, may fall in a range from greater than about 0 nm to less than about 400 nm. Further, a thickness of the second portion PT2'' may be in a range of greater than or equal about 250 nm to less than or equal about 420 nm.

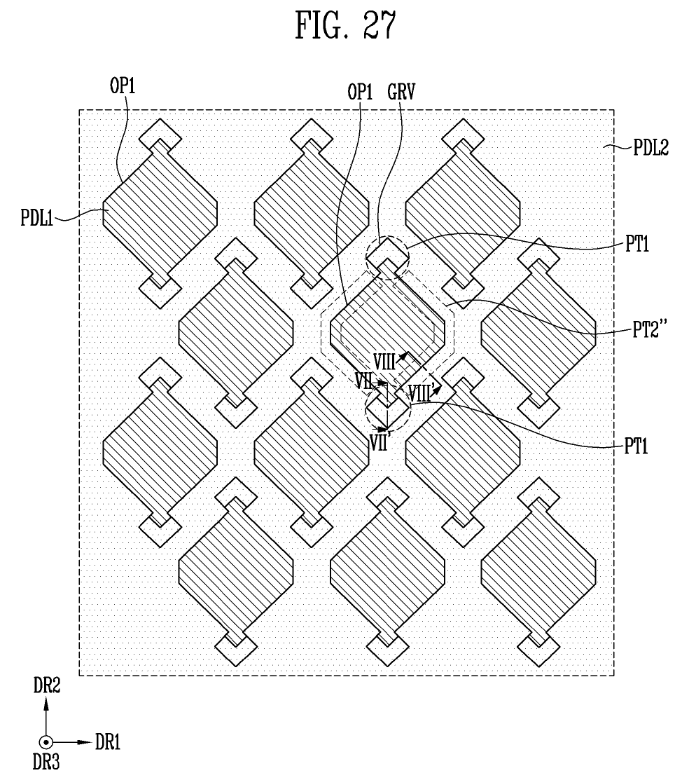

Referring to FIG. 27, the second pixel defining layer PDL2 may be partially etched to form a first opening OP1. The first opening OP1 formed in the second pixel defining layer PDL2 may be formed in an area overlapping with each of the first to third anode electrodes AE1 to AE3, and may expose the first pixel defining layer PDL1.

Further, the first opening OP1 formed in the second pixel defining layer PDL2 may be bent between the second portion PT2'' and the first portion PT1 in a plan view, and may be formed to protrude from the first portion PT1. As a result, the second pixel defining layer PDL2 may have a shape that is more inwardly depressed (e.g., recessed) in the first portion PT1 than the second portion PT2’’ in a plan view.

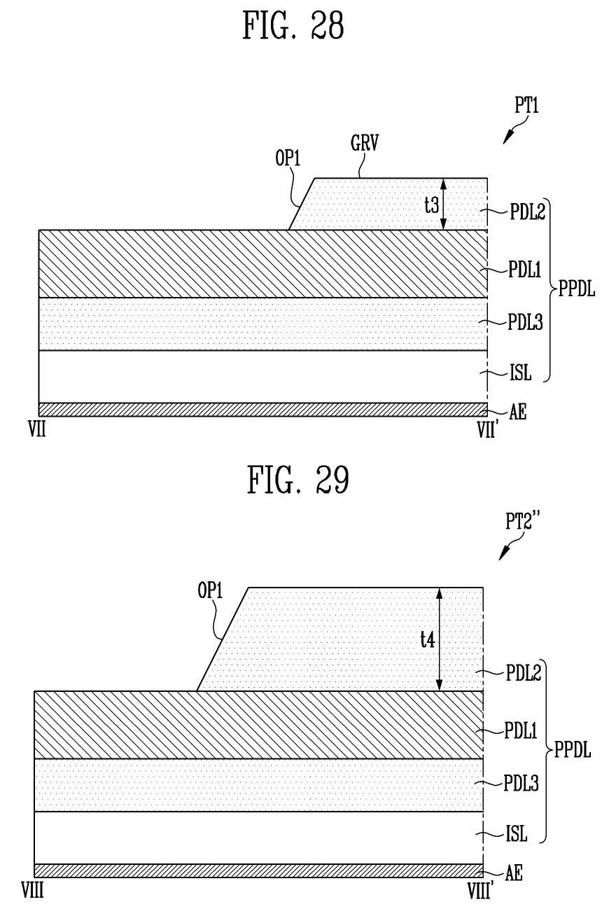

FIG. 28 is a cross-sectional view taken along the line VII-VII' of FIG. 27. FIG. 29 is a cross-sectional view taken along the line VIII-VIII' of FIG. 27. For example, FIG. 28 is a cross-sectional view including a portion corresponding to the first portion PT1 of the preliminary pixel defining layer PPDL, and FIG. 29 is a cross-sectional view including a portion corresponding to the second portion PT2’’ of the preliminary pixel defining layer PPDL.

Referring to FIGS. 28 and 29, the first opening OP1 may be formed throughout a portion corresponding to the first portion PT1 of the second pixel defining layer PDL2 and a portion corresponding to the second portion PT2’’ of the second pixel defining layer PDL2. The first opening OP1 may be formed by etching a portion of the portion corresponding to the first portion PT1 of the second pixel defining layer PDL2 in which the groove GRV is not formed. In other words, the first opening OP1 may be formed by etching a portion of the first portion PT1 of the second pixel defining layer PDL2 having the thickness t4. Thus, only the portion overlapping with the groove GRV remains in the first portion PT1 of the second pixel defining layer PDL2, and accordingly, the first portion PT1 of the second pixel defining layer PDL2 may have a thickness t3 smaller than the thickness t4 of the second portion PT2’’ of the second pixel defining layer PDL2.

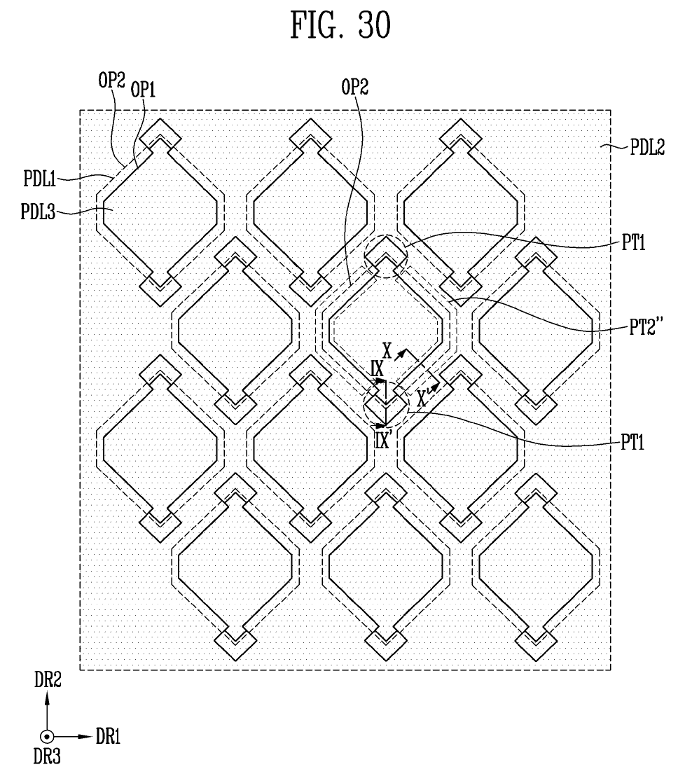

Referring to FIG. 30, the first pixel defining layer PDL1 may be partially etched to form a second opening OP2. The second opening OP2 formed in the first pixel defining layer PDL1 may be formed in an area overlapping with each of the first to third anode electrodes AE1 to AE3, and may overlap with the first opening OP1. Further, the second opening OP2 may expose the third pixel defining layer PDL3.

The second opening OP2 formed in the first pixel defining layer PDL1 may be formed with a larger area than that of the first opening OP1 in a plan view. Accordingly, because the area of the first opening OP1 formed in the second pixel defining layer PDL2 is smaller than the area of the second opening OP2 formed in the first pixel defining layer PDL1 under the second pixel defining layer PDL2, the second pixel defining layer PDL2 may protrude in a direction toward a center of the first opening OP1 relative to the first pixel defining layer PDL1. In other words, the preliminary pixel defining layer PPDL may have an undercut structure at an edge of the first opening OP1.

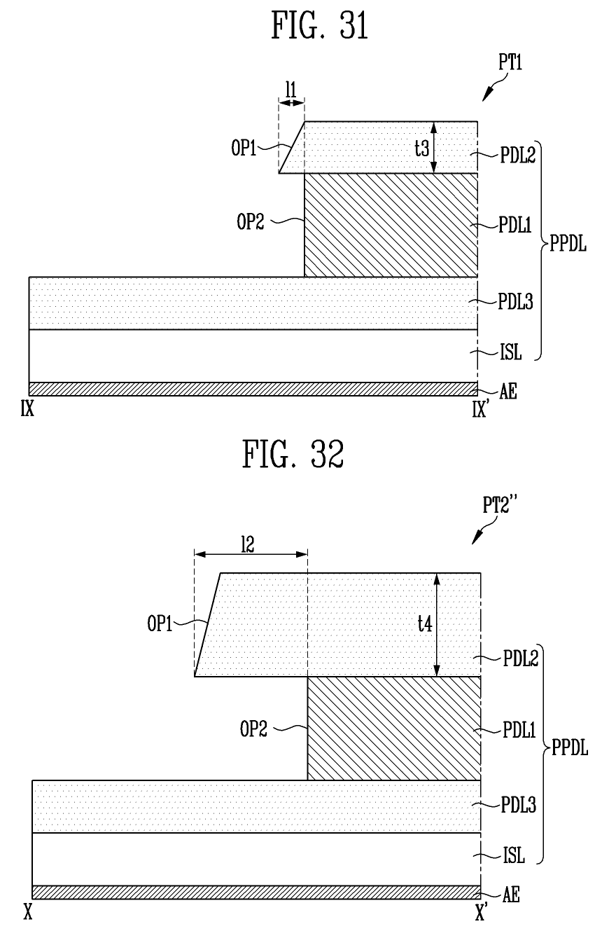

Furthermore, unlike the first opening OP1, the second opening OP2 formed in the first pixel defining layer PDL1 may be formed without an overall bent portion (e.g., a depressed or protruding portion) in the first portion PT1 and the second portion PT2’’ in a plan view. Accordingly, in the undercut structure, a protruding width l1 (e.g., see FIG. 31) of the protrusion at the first portion PT1 and a protruding width l2 (e.g., see FIG. 32) of the protrusion at the second portion PT2’’ may not be constant. In an embodiment, the first opening OP1 formed in the second pixel defining layer PDL2 is formed to protrude from the first portion PT1 more than the second portion PT2'' in a plan view, so that the protruding width l1 of the protrusion at the first portion PT1 in the second pixel defining layer PDL2 may be smaller than the protruding width l2 of the protrusion at the second portion PT2''.

FIG. 31 is a cross-sectional view taken along the line IX-IX' of FIG. 30. FIG. 32 is a cross-sectional view taken along the line X-X' of FIG. 30. For example, FIG. 31 is a cross-sectional view including a portion corresponding to the first portion PT1 of the preliminary pixel defining layer PPDL, and FIG. 32 is a cross-sectional view including a portion corresponding to the second portion PT2’’ of the preliminary pixel defining layer PPDL.

Referring to FIGS. 31 and 32, the first pixel defining layer PDL1 and the second pixel defining layer PDL2 of the preliminary pixel defining layer PPDL may have an undercut structure. The second pixel defining layer PDL2 corresponding to the first portion PT1 and the second pixel defining layer PDL2 corresponding to the second portion PT2 may both protrude relative to the first pixel defining layer PDL1. In this case, the protruding width l1 of the portion corresponding to the first portion PT1 of the second pixel defining layer PDL2 may be different from the protruding width l2 of the portion corresponding to the second portion PT2’’ of the second pixel defining layer PDL2. In an embodiment, the protruding width l1 of the portion corresponding to the first portion PT1 of the second pixel defining layer PDL2 may be smaller than the protruding width l2 of the portion corresponding to the second portion PT2’’ of the second pixel defining layer PDL2. In other words, the protrusion length l1 from the first pixel defining layer PDL1 of the second pixel defining layer PDL2 corresponding to the first portion PT1 may be smaller than the protrusion length l2 from the first pixel defining layer PDL1 of the second pixel defining layer PDL2 corresponding to the second portion PT2’’.

In an embodiment, the protrusion length l1, from the first pixel defining layer PDL1, of the second pixel defining layer PDL2 corresponding to the first portion PT1 may be in a range of greater than about 0 nm to less than about 110 nm. Furthermore, the protrusion length l2, from the first pixel defining layer PDL1, of the second pixel defining layer PDL2 corresponding to the second portion PT2'' may be in a range from about 35 nm or more to about 250 nm or less.

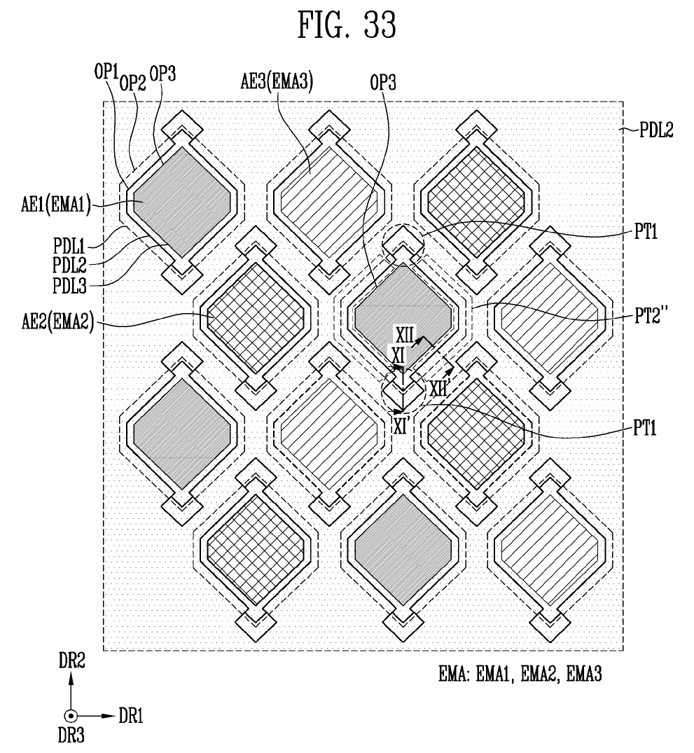

Referring to FIG. 33, the third pixel defining layer PDL3 may be partially etched to form a third opening OP3. The third opening OP3 formed in the third pixel defining layer PDL3 may be formed in an area overlapping with each of the first to third anode electrodes AE1 to AE3, and may overlap with the first opening OP1 and the second opening OP2.

The third opening OP3 formed in the third pixel defining layer PDL3 may be formed in a smaller area than those of the first opening OP1 and the second opening OP2 in a plan view. However, the present disclosure is not limited thereto.

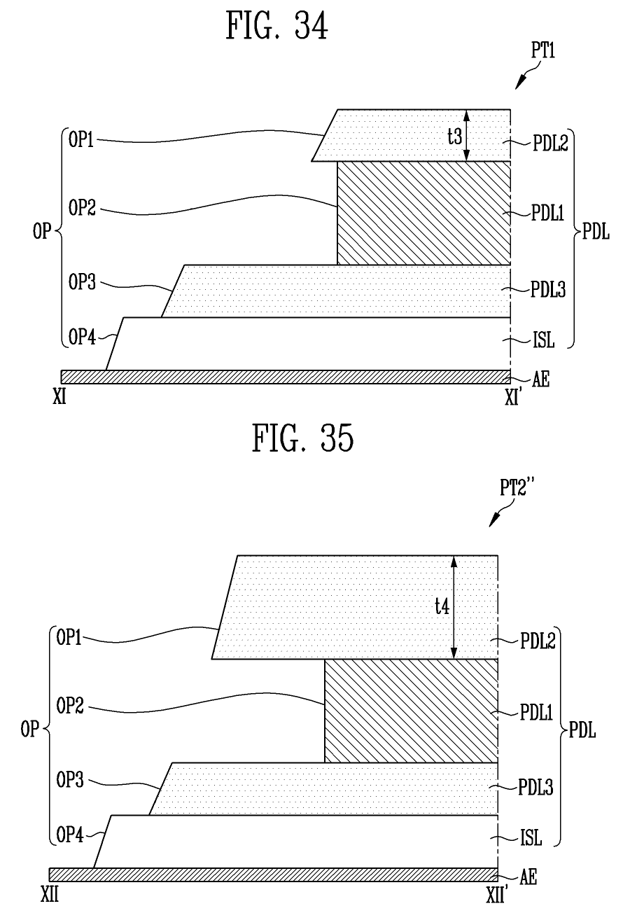

Further, the inorganic insulating layer ISL may be partially etched to form a fourth opening OP4 overlapping with the first to third openings OP1 to OP3. The fourth opening OP4 may overlap with each of the first to third anode electrodes AE1 to AE3, and may expose each of the first to third anode electrodes AE1 to AE3. Accordingly, an opening OP (e.g., see FIG. 34) including the first to fourth openings OP1 to OP4 may be formed.

As the inorganic insulating layer ISL and each of the first to third pixel defining layers PDL1 to PDL3 are etched to form an opening OP in the preliminary pixel defining layer PPDL, a pixel defining layer PDL including the inorganic insulating layer ISL and the first to third pixel defining layers PDL1 to PDL3 with the opening OP may be formed.

FIG. 34 is a cross-sectional view taken along the line XI-XI' of FIG. 33. FIG. 35 is a cross-sectional view taken along the line XII-XII' of FIG. 33. For example, FIG. 34 is a cross-sectional view including a portion corresponding to the first portion PT1 of the pixel defining layer PDL, and FIG. 35 is a cross-sectional view including a portion corresponding to the second portion PT2’’ of the pixel defining layer PDL.

Referring to FIGS. 34 and 35, the third opening OP3 having an area smaller than those of the first opening OP1 and the second opening OP2 may be formed in the third pixel defining layer PDL3, and the fourth opening OP4 having an area smaller than that of the third opening OP3 may be formed in the inorganic insulating layer ISL. The third pixel defining layer PDL3 and the inorganic insulating layer ISL may protrude in a direction toward a center of the opening OP more than the first pixel defining layer PDL1 and the second pixel defining layer PDL2. However, the present disclosure is not limited thereto.

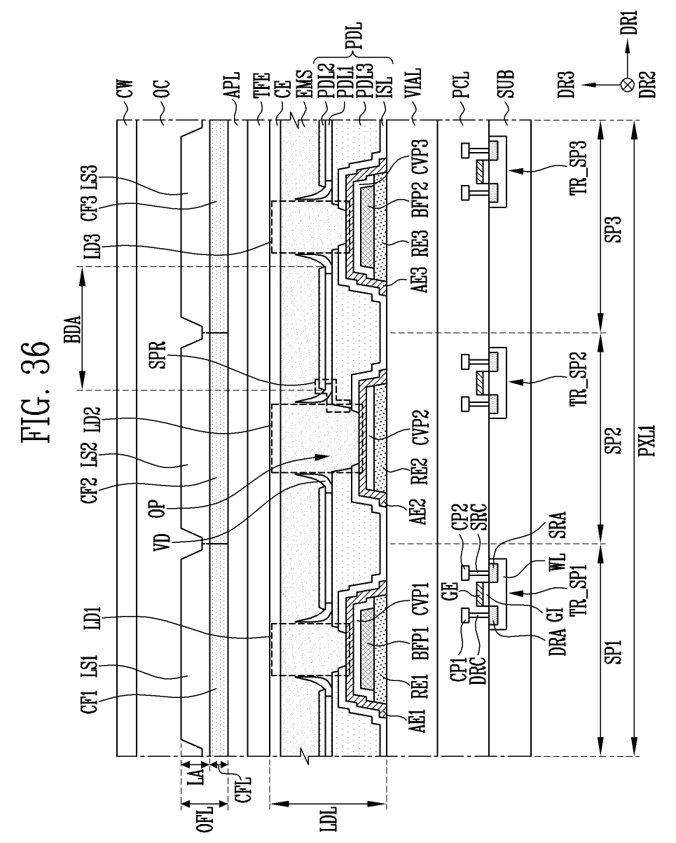

Referring to FIG. 36, the light-emitting structure EMS may fill the opening OP of the pixel defining layer PDL, and may be formed entirely on the pixel defining layer PDL. The light-emitting structure EMS may extend across the first to third sub-pixels SP1 to SP3. In this case, at least some of the layers within the light-emitting structure EMS may be disconnected or bent at the boundaries between the first to third sub-pixels SP1 to SP3. However, the present disclosure is not limited thereto.

A cathode electrode CE may be formed on the light-emitting structure EMS. The cathode electrode CE may extend across the first to third sub-pixels SP1 to SP3. An encapsulation layer TFE may be formed on the cathode electrode CE. An optical functional layer OFL may be formed on the encapsulation layer TFE. In this case, the optical functional layer OFL may be attached to the encapsulation layer TFE via an adhesive layer APL. A color filter layer CFL included in the optical functional layer OFL may be formed on the adhesive layer APL. On the color filter layer CFL, a lens array LA included in the optical functional layer OFL may be formed. An overcoat layer OC may be formed on the lens array LA. A cover window CW may be formed on the overcoat layer OC.

In an embodiment, because the protrusion length l2 of the second portion PT2'' of the pixel defining layer PDL is formed longer than the protrusion length l1 of the first portion PT1, and because the thickness t4 of the second portion PT2'' is formed larger than the thickness t3 of the first portion PT1, the light-emitting structure EMS on the pixel defining layer PDL may be more easily disconnected due to the undercut structure in the second portion PT2'' than in the first portion PT1. In other words, by forming the structure of the pixel defining layer PDL disposed between the emission areas EMA for emitting light of the same color as each other (e.g., the structure of the first portion PT1 of FIG. 34) differently from the structure of the pixel defining layer PDL disposed between the emission areas EMA for emitting light of different colors from each other (e.g., the structure of the second portion PT2’’ of FIG. 35), the cathode electrode CE may not be disconnected between the emission areas EMA for emitting light of the same color as each other (e.g., the first portion PT1), and the charge generation layer CGL may be disconnected between the emission areas EMA for emitting light of different colors from each other (e.g., the second portion PT2’’).

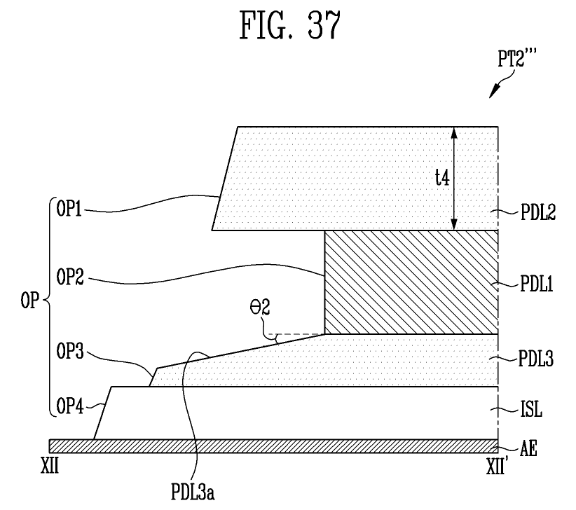

FIG. 37 is a cross-sectional view illustrating a method of manufacturing a display device according to another embodiment. For example, FIG. 37 may illustrate a process of additionally etching the third pixel defining layer PDL3 through an additional process after that of FIG. 35.

Referring to FIGS. 34 and 37, after the third opening OP3 is formed in the third pixel defining layer PDL3, a side surface PDL3a having an incline may be formed in a second portion PT2''' of the third pixel defining layer PDL3. In other words, an upper surface of the second portion PT2''' of the third pixel defining layer PDL3 may be etched through an isotropic etching process. In this case, a partial exposure method may be used in the process of etching the second portion PT2’’’ of the third pixel defining layer PDL3, and the first portion PT1 of the third pixel defining layer PDL3 may not be etched (e.g., see FIG. 34).

In an embodiment, a slope θ2 of the side surface PDL3a of the second portion PT2’’’ of the third pixel defining layer PDL3 may be formed larger than a slope of the side surface of the first portion PT1, so that it may be easier to break the light-emitting structure EMS due to the undercut structure in the second portion PT2’’’ than in the first portion PT1.

The display device according to some embodiments may be applied to various suitable electronic devices. An electronic device according to an embodiment includes the display device described above, and may further include modules or devices having other additional functions in addition to the display device.

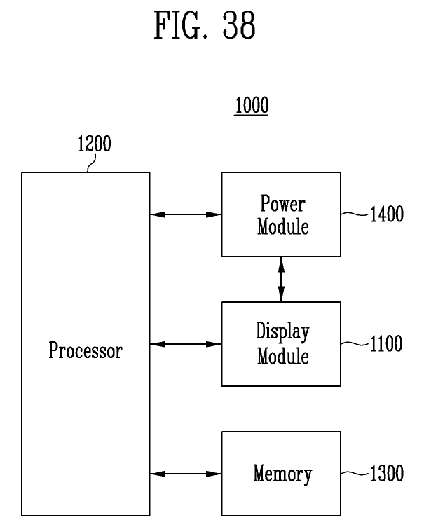

FIG. 38 is a block diagram of an electronic device according to an embodiment.

Referring to FIG. 38, the electronic device 1000 according to an embodiment may include a display module 1100, a processor 1200, a memory 1300, and a power module (e.g., a power supply) 1400.

The processor 1200 may include at least one of a central processing unit (CPU), an application processor (AP), a graphics processing unit (GPU), a communication processor (CP), an image signal processor (ISP), and/or a controller.

The memory 1300 may store data information used for the operations of the processor 1200 or the display module 1100. When the processor 1200 executes an application stored in the memory 1300, image data signals and/or input control signals may be provided to the display module 1100, and the display module 1100 may process the provided signals to output image information via the display screen.

The power module 1400 may include a power supply module, such as a power adapter or battery unit (e.g., a battery), and a power conversion module that converts the power supplied by the power supply module to generate the power used for operations of the electronic device 1000.

At least one of the above-described components of the electronic device 1000 may be included in the display device according to some embodiments as described above. In addition, in terms of functionality, some of the individual modules included in one module may be included in the display device, and others may be provided separately from the display device. For example, the display module 1100 may be included in the display device, whereas the processor 1200, the memory 1300, and the power module 1400 may not be included in the display device, and instead, may be provided separately in the electronic device 1000.

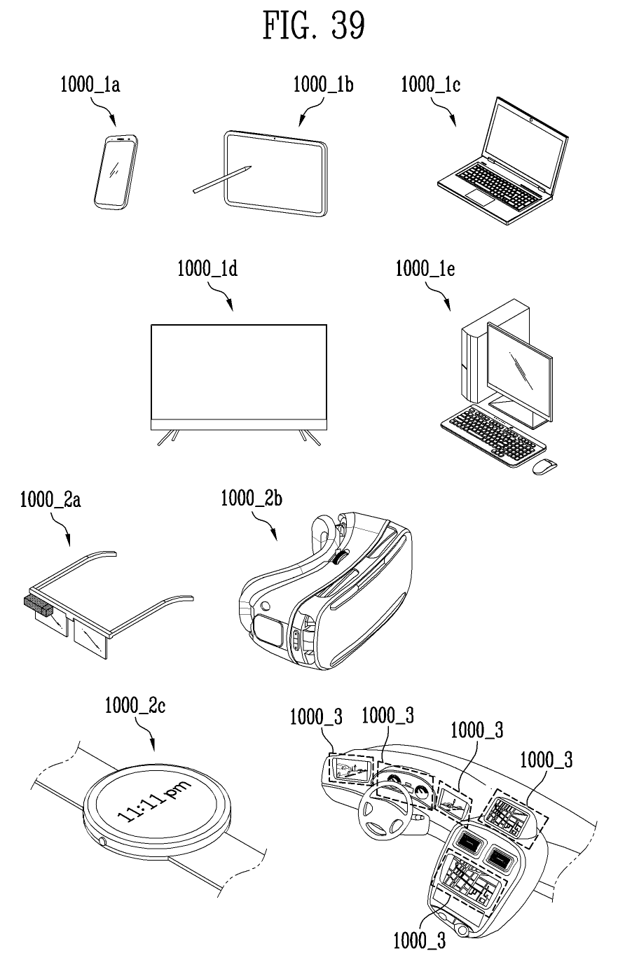

FIG. 39 is a schematic diagram of an electronic device according to some embodiments.

Referring to FIG. 39, various electronic devices to which the display device according to some embodiments may be applied may include image display electronic devices, such as a smartphone 1000_1a, a tablet PC 1000_1b, a laptop 1000_1c, a TV 1000_1d, and a desktop monitor 1000_1e, as well as wearable electronic devices including a display module, such as smart glasses 1000_2a, a head-mounted display 1000_2b, and a smart watch 1000_2c, and automotive electronic devices 1000_3 that incorporate display modules, such as a vehicle’s instrument cluster, a center fascia, a Center Information Display (CID) mounted on a dashboard, a room mirror display, and the like.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
anode electrodes on the substrate, and overlapping with emission areas, respectively; and
a pixel defining layer covering an edge of each of the anode electrodes, defining each of the emission areas, and having an opening overlapping with each of the anode electrodes, the pixel defining layer comprising:
a first portion between emission areas adjacent to each other in a plan view and configured to emit light of a same color as each other from among the emission areas; and
a second portion between emission areas configured to emit light of different colors from each other from among the emission areas,
wherein each of the first portion and the second portion comprises a protrusion protruding from an edge of the opening in a direction toward a center of the opening to have an undercut structure at the edge of the opening, and
wherein a protruding width of a portion of the protrusion corresponding to the first portion and a protruding width of a portion of the protrusion corresponding to the second portion are different from each other.

2. The display device of claim 1, wherein the protruding width of the portion of the protrusion corresponding to the first portion is smaller than the protruding width of the portion corresponding to the second portion.

3. The display device of claim 2, wherein the protruding width of the portion of the protrusion corresponding to the first portion is in a range of greater than 0 nm and less than 110 nm, and
wherein the protruding width of the portion of the protrusion corresponding to the second portion is in a range of greater than or equal to 35 nm and less than or equal to 250 nm.

4. The display device of claim 1, wherein the pixel defining layer comprises:
a first pixel defining layer on the anode electrodes; and
a second pixel defining layer on the first pixel defining layer, and having a width greater than a width of the first pixel defining layer.

5. The display device of claim 4, wherein the second pixel defining layer comprises the protrusion protruding from the first pixel defining layer in the direction toward the center of the opening in a plan view.

6. The display device of claim 5, wherein a protrusion length, from the first pixel defining layer in a plan view, of a portion of the second pixel defining layer corresponding to the first portion is less than a protrusion length, from the first pixel defining layer in a plan view, of a portion of the second pixel defining layer corresponding to the second portion.

7. The display device of claim 4, wherein a thickness of a portion of the second pixel defining layer corresponding to the first portion is less than a thickness of a portion of the second pixel defining layer corresponding to the second portion.

8. The display device of claim 4, wherein the pixel defining layer further comprises a third pixel defining layer between the first pixel defining layer and the anode electrodes.

9. The display device of claim 8, wherein the third pixel defining layer has a width greater than the width of the first pixel defining layer.

10. The display device of claim 8, wherein a slope of a side surface of a portion of the third pixel defining layer corresponding to the first portion is smaller than a slope of a side surface of a portion of the third pixel defining layer corresponding to the second portion.

11. The display device of claim 1, further comprising:
a light-emitting structure on the pixel defining layer, and comprising light-emitting units, and a charge generation layer between the light-emitting units; and
a cathode electrode on the light-emitting structure, and connected entirely through an area overlapping with the first portion of the pixel defining layer,
wherein the charge generation layer is discontinuous in an area overlapping with the second portion of the pixel defining layer.

12. A display device comprising:
a substrate;
anode electrodes on the substrate, and overlapping with emission areas, respectively; and
a pixel defining layer covering an edge of each of the anode electrodes, defining each of the emission areas, and having an opening overlapping with each of the anode electrodes, the pixel defining layer comprising:
a first portion between emission areas adjacent to each other in a plan view and configured to emit light of a same color as each other from among the emission areas; and
a second portion between emission areas configured to emit light of different colors from each other from among the emission areas,
wherein a thickness of the first portion and a thickness of the second portion are different from each other.

13. The display device of claim 12, wherein the thickness of the first portion is less than the thickness of the second portion.

14. The display device of claim 13, wherein the thickness of the first portion is in a range of greater than 0 nm and less than 400 nm, and
wherein the thickness of the second portion is in a range of greater than or equal to 250nm and less than or equal to 420nm.

15. The display device of claim 12, wherein the pixel defining layer comprises:
a first pixel defining layer on the anode electrodes; and
a second pixel defining layer on the first pixel defining layer, and having a width greater than a width of the first pixel defining layer.

16. The display device of claim 15, wherein a thickness of a portion of the second pixel defining layer corresponding to the first portion is less than a thickness of a portion of the second pixel defining layer corresponding to the second portion.

17. The display device of claim 15, wherein the pixel defining layer further comprises a third pixel defining layer between the first pixel defining layer and the anode electrodes.

18. The display device of claim 17, wherein the third pixel defining layer has a width greater than the width of the first pixel defining layer.

19. The display device of claim 17, wherein a slope of a side surface of a portion of the third pixel defining layer corresponding to the first portion is less than a slope of a side surface of a portion of the third pixel defining layer corresponding to the second portion.

20. An electronic device comprising:
a processor; and
a display device configured to display an image under control of the processor, the display device comprising:
a substrate;
anode electrodes on the substrate, and overlapping with emission areas, respectively; and
a pixel defining layer covering an edge of each of the anode electrodes, defining each of the emission areas, and having an opening overlapping with each of the anode electrodes, the pixel defining layer comprising:
a first portion between emission areas adjacent to each other in a plan view and configured to emit light of a same color as each other from among the emission areas; and
a second portion between emission areas configured to emit light of different colors from each other from among the emission areas,
wherein each of the first portion and the second portion comprises a protrusion protruding from an edge of the opening in a direction toward a center of the opening to have an undercut structure at the edge of the opening,
wherein a protruding width of a portion of the protrusion corresponding to the first portion and a protruding width of a portion of the protrusion corresponding to the second portion are different from each other, and
wherein a number of pixels per inch (ppi) of the display device is greater than or equal to 1000 ppi.
